(19) United States
(12) Patent Application Publication
(10) Pub. No.: US 2026/0068197 A1
(43) Pub. Date: Mar. 5, 2026

(54) METHODS FOR MANUFACTURING SEMICONDUCTOR STRUCTURES

(71) Applicant: Peiching LING, Taipei (TW)

(72) Inventors: Peiching LING, San Jose, CA (US); Nanray WU, Miaoli (TW); Liang-Gi YAO, Hsinchu City (TW)

(21) Appl. No.: 19/104,359

(22) PCT Filed: Feb. 19, 2024
(86) PCT No.: PCT/US24/16407

§ 371 Date: Feb. 17, 2025

Related U.S. Application Data
(60) Provisional application No. 63/387,972, filed on Dec. 19, 2022.

(51) Int. Cl. H10D 8/01; H01L 21/265

(52) U.S. Cl. CPC H10D 8/051; H10D 8/045

(57) ABSTRACT

The present disclosure relates to a method for manufacturing a semiconductor structure. The method comprises providing a first structure. The first structure comprises a first substrate. The method comprises providing a second structure. The second structure comprises a second substrate and a first device metal layer on and in contact with the second substrate. The second substrate comprises a single crystalline semiconductor material and an implanted hydrogen layer. The method comprises bonding the first structure and the second structure by a bonding layer to form a bonded structure. The method comprises removing a portion of the second substrate from approximately the implanted hydrogen layer to form a first semiconductor layer. The method comprises patterning the first semiconductor layer. The method comprises forming at least one of a second device metal layer and a second conductive metal layer.

### RELATED APPLICATION

This application claims priority to U.S. Provisional Patent Application Ser. No. 63/387,972, filed on Dec. 19, 2022, entitled “Structures of Vertical Diodes and Memory Cells and Manufacturing Processes thereof,” which is incorporated herein by reference in its entirety.

### BACKGROUND OF THE INVENTION

### Field of the Invention

The present disclosure relates to methods for manufacturing semiconductor structures. In particular, some embodiments of the present disclosure relate to methods for manufacturing semiconductor structures including vertical Schottky diode(s) or vertical PN diode(s).

### Description of Related Art

The demand for non-volatile memory is increasing due to the continuous development of portable devices. As the dimension of the devices is reduced, non-volatile memory with greater efficiency, faster memory access, and low-power consumption become hot topics for fulfilling the market. However, there are several technical issues that need to be overcome to provide the desired properties. First, in a conventional non-volatile memory device, a transistor is used as a selector. When the size of the transistor is reduced and the integration density is increased, the space between these devices is also decreased. The inter-device space becomes critical to the performance of the devices, and when the space is too small, these devices may interfere with each other. Second, the transistor has a saturation region, the current it can provide is limited by its inherent characteristics. When a non-volatile memory device has a high current density requirement, such as a magnetoresistive random access memory (MRAM) device, the size of a transistor capable of providing fulfilling current density would be significantly large. Third, the channel region of the transistor forming in a semiconductor substrate may suffer from current leakage, which may decrease the efficiency and result in high power consumption.

When using a transistor as the selector of the non-volatile memory device, compromise has to be made to balance the feature size and the inter-device space, and each device's performance may need to be optimized. When more devices are put into one chip, parasitic capacitance and power consumption may increase due to the small inter-device space and current leakage. There is still a need to improve the structure and process for greater efficiency, faster memory access, and low power consumption of memory devices.

### SUMMARY

According to the present disclosure, a method for manufacturing a semiconductor structure is provided. The method comprises providing a first structure. The first structure comprises a first substrate. The method comprises providing a second structure. The second structure comprises a second substrate and a first device metal layer on and in contact with the second substrate. The second substrate comprises a single crystalline semiconductor material and an implanted hydrogen layer. The method comprises bonding the first structure and the second structure by a bonding layer to form a bonded structure. The method comprises removing a portion of the second substrate from approximately the implanted hydrogen layer to form a first semiconductor layer. The method comprises patterning the first semiconductor layer. The method comprises forming at least one of a second device metal layer and a second conductive metal layer.

### BRIEF DESCRIPTION OF THE DRAWINGS

FIGS. 1A to 1H are schematic diagrams illustrating intermediate stages in the manufacture of a semiconductor structure according to one embodiment of the present disclosure.

FIGS. 2A to 2E are schematic diagrams illustrating intermediate stages in the manufacture of a semiconductor structure according to one embodiment of the present disclosure.

FIG. 3 is a schematic view to illustrate an embodiment of a memory device according to the present disclosure.

FIGS. 4A to 4F are schematic diagrams illustrating intermediate stages in the manufacture of a semiconductor structure according to one embodiment of the present disclosure.

FIGS. 5A to 5C are schematic diagrams illustrating intermediate stages in the manufacture of a semiconductor structure according to one embodiment of the present disclosure.

FIGS. 6A to 6G are schematic diagrams illustrating intermediate stages in the manufacture of a semiconductor structure according to one embodiment of the present disclosure.

FIG. 7 is a schematic view to illustrate an embodiment of a memory device according to the present disclosure.

FIGS. 8A to 8D are schematic diagrams illustrating intermediate stages in the manufacture of a semiconductor structure according to one embodiment of the present disclosure.

FIGS. 9A to 9C are schematic diagrams illustrating intermediate stages in the manufacture of a semiconductor structure according to one embodiment of the present disclosure.

FIG. 10 is a schematic view to illustrate an embodiment of a memory device according to the present disclosure.

FIGS. 11A to 11E are schematic diagrams illustrating intermediate stages in the manufacture of a semiconductor structure according to one embodiment of the present disclosure.

FIGS. 12A to 12C are schematic diagrams illustrating intermediate stages in the manufacture of a semiconductor structure according to one embodiment of the present disclosure.

FIGS. 13A to 13G are schematic diagrams illustrating intermediate stages in the manufacture of a semiconductor structure according to one embodiment of the present disclosure.

FIG. 14 is a schematic view to illustrate an embodiment of a memory device according to the present disclosure.

### DETAILED DESCRIPTION OF PREFERRED EMBODIMENTS

The terminology used in the description presented below is intended to be interpreted in its broadest reasonable manner, even though it is used in conjunction with a detailed description of certain specific embodiments of the technology. Certain terms may even be emphasized below; however, any terminology intended to be interpreted in any restricted manner will be specifically defined as such in this Detailed Description section. Components and achievement of a semiconductor structure or a memory device, according to the present disclosure may be illustrated in the following drawings and embodiments. However, the size and shape shown on drawings for the semiconductor structure or the memory device do not limit the features of the present disclosure.

The phrase “on” used in this application can mean directly on or indirectly on with intervening elements or layers. The spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

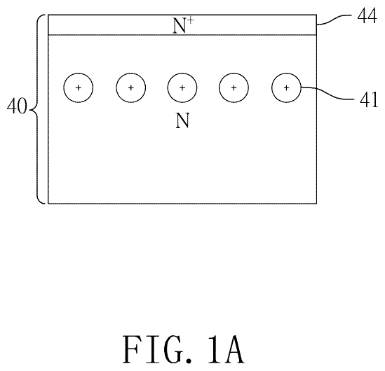

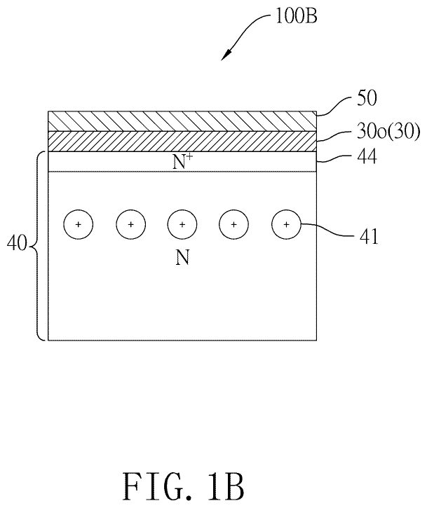

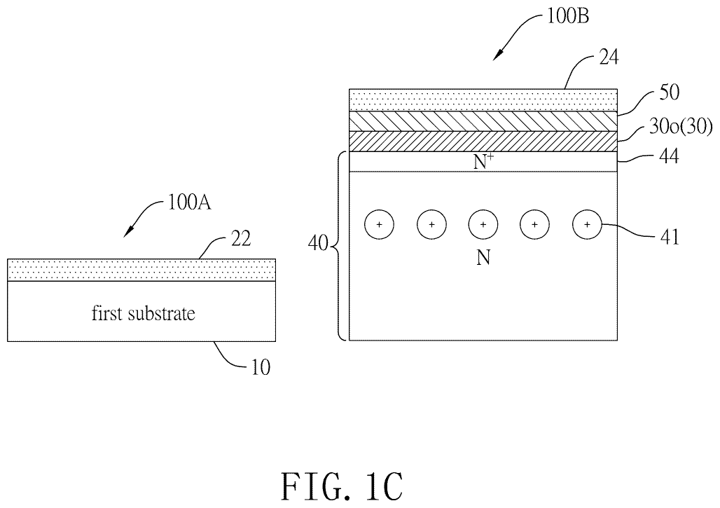

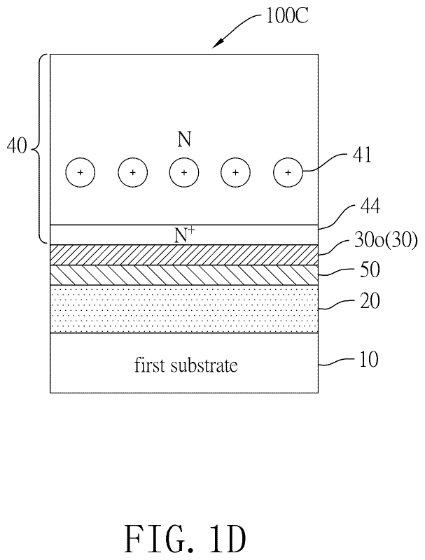

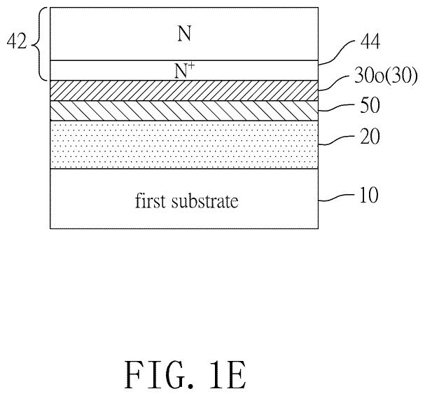

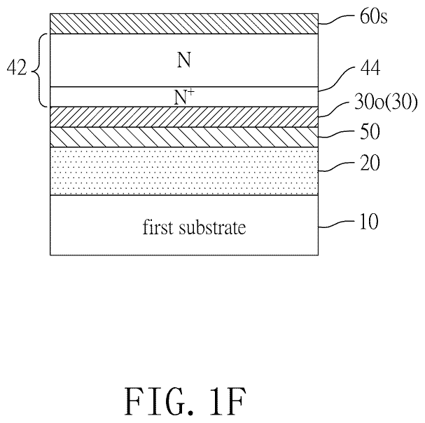

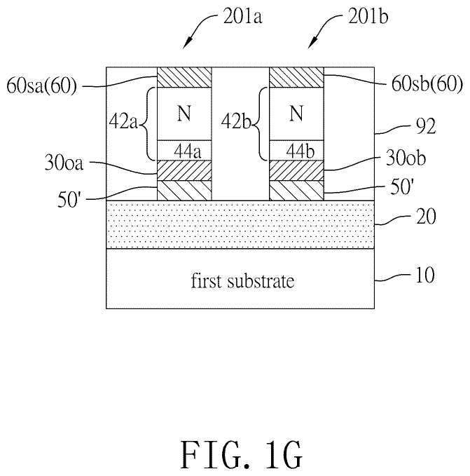

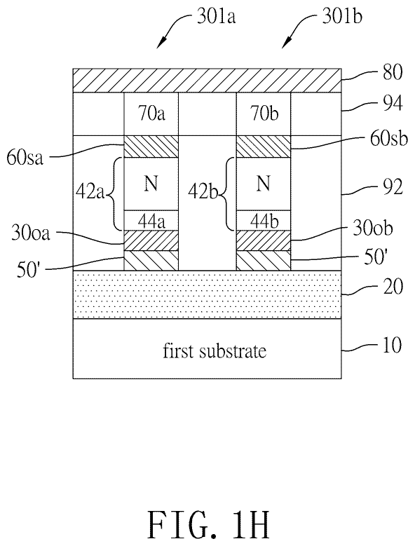

FIGS. 1A to 1H are schematic diagrams illustrating intermediate stages in the manufacture of a semiconductor structure according to one embodiment of the present disclosure.

As shown in FIG. 1A, a second substrate 40 is provided (step (b1)). The second substrate 40 may comprises a single crystalline semiconductor material, including but not limited to silicon, germanium, silicon germanium, gallium arsenide (GaAs), indium phosphide (InP), silicon carbide (SiC), or gallium nitride (GaN). In some embodiments, the second substrate 40 is of a first conductivity type. For example, the second substrate 40 may be doped with n-type dopants, such as phosphorus, arsenic, antimony, bismuth, the like, or combinations thereof. In some embodiments, the doping concentration of the second substrate 40 may be from about 1.0×10¹⁴ atoms/cm³ to about 5.0×10¹⁷ atoms/cm³. These values are merely examples and are not intended to be limiting. In some other embodiments, the second substrate may be doped with p-type dopants, such as boron, aluminum, gallium, indium, the like, or combinations thereof.

The second substrate 40 may comprise a first heavily-doped layer 44 extending from a top surface of the second substrate 40. The first heavily-doped layer 44 may be formed by ion implantation or epitaxial growth. The first heavily-doped layer 44 is of the first conductivity type as described above. The first heavily-doped layer 44 may have a higher doping concentration than that of the second substrate 40. In some embodiments, the doping concentration of the first heavily-doped layer 44 may be from about 1.0×10¹⁸ atoms/cm³ to about 3.0×10²⁰ atoms/cm³. In one embodiment, the thickness of the first heavily-doped layer 44 may be in a range between 2 nm and 100 nm. These values are merely examples and are not intended to be limiting. In the embodiment shown in FIG. 1A, the first heavily-doped layer 44 is unpatterned.

A hydrogen layer 41 may be implanted into the second substrate 40 (step (b2)). In some embodiments, the implanted hydrogen layer 41 may be formed at a depth of about 4×10⁻⁵ to 8×10⁻⁵ inch (about 1 μm to 2 μm) from the top surface of the second substrate 40. Proper implantation voltage can be selected to have the peak of the implanted hydrogen occur at the desired depth. For example, hydrogen ions are implanted into the second substrate 40 using a dosage of 1×10¹⁶ to 2×10¹⁷ ions/cm² at an implantation energy of 50 to 150 KeV. These values are merely examples and are not intended to be limiting. The implantation may be conducted before or after the formation of the first heavily-doped layer 44 as long as the implanted hydrogen layer 41 will not be damaged by the succeeding processes. In some embodiments, the hydrogen layer 41 are implanted after the formation of the first heavily-doped layer 44. As shown in FIGS. 1A and 1B, the implantation may be conducted before the formation of the first device metal layer 30.

As shown in FIG. 1B, a first device metal layer 30 is formed on the second substrate 40 (step (b3)). The first device metal layer 30 may be formed in contact with the second substrate 40; specifically, the first device metal layer 30 may be formed in contact with the first heavily-doped layer 44. In the embodiment shown in FIG. 1B, the first device metal layer 30 comprises an Ohmic material layer 300. The Ohmic material layer 300 may comprise suitable metal, alloy, or conductive metal compound, e.g., Mo, Ag, TiN, or combinations thereof, such that an Ohmic junction can be formed between the Ohmic material layer 300 and the first heavily-doped layer 44 (or the second substrate 40). The Ohmic material layer 300 may be formed by deposition such as chemical vapor deposition (CVD), physical vapor deposition (PVD), or atomic layer deposition (ALD). In the embodiment shown in FIG. 1B, the Ohmic material layer 300 is unpatterned. In some embodiments, the thickness of the Ohmic material layer 300 may be in a range between 2 nm and 100 nm. These values are merely examples and are not intended to be limiting.

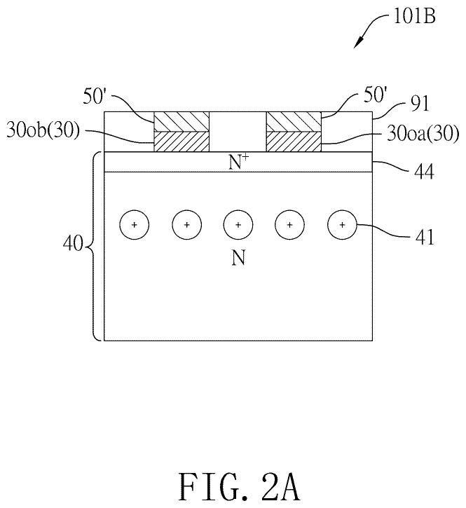

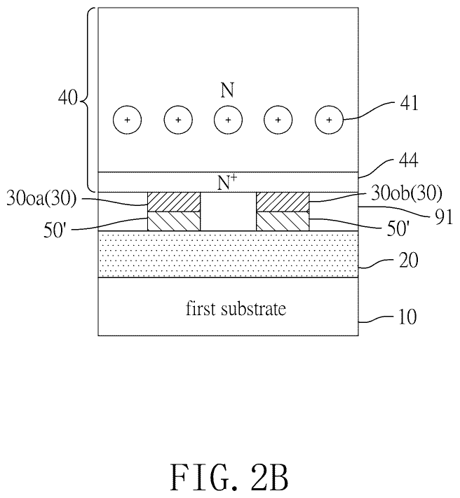

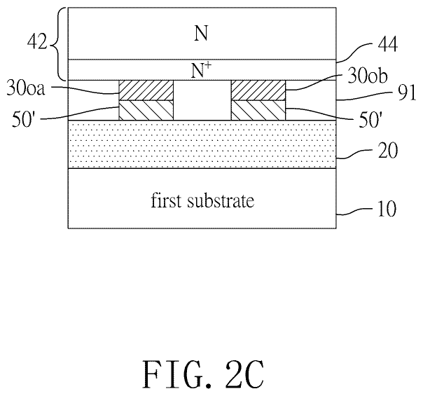

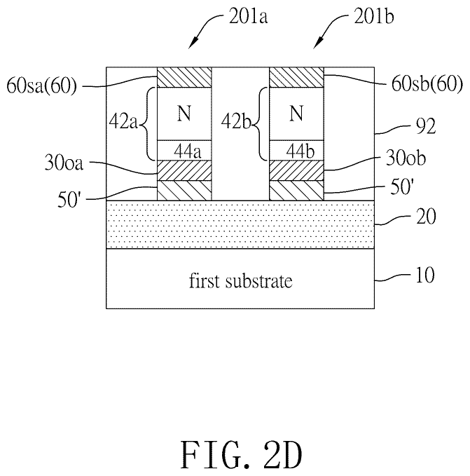

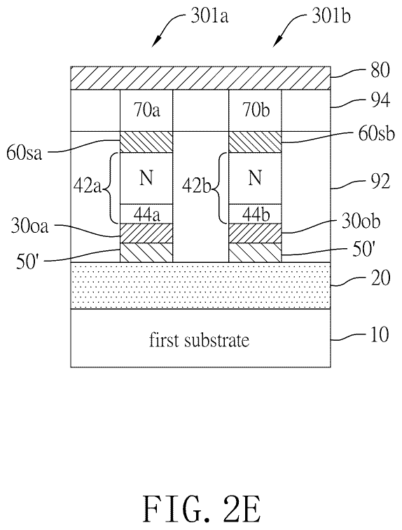

As shown in FIG. 1B, a first conductive metal layer 50 may be formed on the first device metal layer 30. In the embodiment shown in FIG. 1B, the first conductive metal layer 50 comprises an unpatterned conductive metal material layer. However, in some other embodiments (e.g., in the embodiment shown in FIGS. 2A to 2E), the first conductive metal layer may comprise patterned conductive features. The first conductive metal layer 50 may comprise copper, aluminum, tungsten, some other suitable material(s), or a combination of the foregoing and may be formed by deposition such as chemical vapor deposition (CVD), physical vapor deposition (PVD), or atomic layer deposition (ALD).

Referring to FIG. 1B, a second structure 100B is provided (step (b)). The second structure 100B comprises a second substrate 40 and a first device metal layer 30 on and in contact with the second substrate 40. The second substrate 40 may comprise an implanted hydrogen layer 41. In the embodiment shown in FIG. 1B, the second structure 100B further comprises a first conductive metal layer 50, wherein the first device metal layer 30 is disposed between the first conductive metal layer 50 and the second substrate 40. In the embodiment shown in FIG. 1B, the second substrate 40 further comprises a first heavily-doped layer 44 in contact with the first device metal layer 30.

As shown in FIG. 1C, a first structure 100A is provided (step (a)). The first structure 100A comprises a first substrate 10. The first substrate 10 may comprise single crystalline semiconductor material or polycrystalline semiconductor material, including but not limited to silicon, germanium, silicon germanium, gallium arsenide (GaAs), indium phosphide (InP), silicon carbide (SiC), or gallium nitride (GaN), glass, or ceramic. In some embodiments, the first substrate 10 may include one or more active device, such as a transistor or the like, and/or one or more passive device, such as a capacitor, resistor, diode, or the like.

In the embodiment shown in FIG. 1C, a first dielectric layer 22 is formed on the first substrate 10, and a second dielectric layer 24 is formed on the first device metal layer 30 (step (c)). Specifically, the second dielectric layer 24 may be formed over the first conductive metal layer 50. The first dielectric layer 22 and/or the second dielectric layer 24 may comprise silicon oxide and may be formed by thermal oxidation or deposition such as CVD, PVD, or ALD. As shown in FIGS. 1C and 1D, the first dielectric layer 22 and the second dielectric layer 24 are formed before bonding of the first structure 100A and the second structure 100B. In some other embodiments, only one of the first dielectric layer 22 and the second dielectric layer 24 is formed.

As shown in FIG. 1D, the second structure 100B is flipped and bonded onto the first structure 100A. The first structure 100A and the second structure 100B are bonded by a bonding layer 20 to form a bonded structure 100C (step (c)). For example, the first structure 100A and the second structure 100B may be bonded by a fusion bonding process, such as a hydrophilic fusion bonding process. In some embodiments, both the first dielectric layer 22 and the second dielectric layer 24 are cleaned by conventional cleaning techniques such as the RCA wafer cleaning procedure. The cleaning process removes surface impurities and particles from the surfaces of the dielectric layers 22 and 24. In one embodiment, hydroxyl groups (OH⁻) are formed on the surfaces to be bonded due to the presence of electric charges of atoms. Hydrogen bonds may be formed between the first dielectric layer 22 and the second dielectric layer 24, then, an annealing process may be performed to form chemical bonds (e.g., Si—O bond) between the surfaces of the first dielectric layer 22 and the second dielectric layer 24. As shown in FIG. 1D, the first dielectric layer 22 and the second dielectric layer 24 are bonded to form the bonding layer 20. The bonding layer 20 may comprise silicon oxide. In one embodiment, a thickness of the bonding layer 20 may be in a range between 0.2 nm and 1000 nm. These values are merely examples and are not intended to be limiting.

As shown in FIG. 1E, a portion of the second substrate 40 is removed from approximately the implanted hydrogen layer 41 to form a first semiconductor layer 42 (step (d)). The portion of the second substrate 40 may be removed by heating the bonded structure 100C at a first temperature. A first temperature is usually below 400° C. to avoid damage to the semiconductor device(s) fabricated in the first substrate 10 and/or the second substrate 40, if there is any. In some embodiments, the portion of the second substrate 40 may be removed by other methods, as long as a portion of the second substrate 40 has been sufficiently weakened by previous hydrogen implantation and some subsequent annealing. For example, the bonded structure 100C can be cleaved by applying mechanical pressure to the second substrate 40 or by dipping and quenching the bonded structure 100C in liquid nitrogen.

The portion of the second substrate 40 remaining on the bonded structure 100C may be less than 3 μm based on the implanted depth of the implanted hydrogen layer 41. After removal, the separated surface of the second substrate 40 may be polished by chemical mechanical polishing (CMP) to planarize and minimize the non-uniformity of the separated surface. Other approaches such as etching may be used for the same purpose. An etch stop layer may need to be deposited in advance when etching is used to planarize and minimize the non-uniformity of the separated surface of the second substrate 40. As such, the first semiconductor layer 42 is formed. The first semiconductor layer 42 may be of a first conductivity type as described above. In some embodiments, the thickness of the first semiconductor layer 42 may be in a range between 5 nm and 200 nm. These values are merely examples and are not intended to be limiting.

As shown in FIGS. 1F and 1G, the first semiconductor layer 42 is patterned to form a plurality of semiconductor layers 42a and 42b (step (e)). The first heavily-doped layer 44 may also be patterned to form a plurality of heavily-doped regions 44a and 44b. The first semiconductor layer 42 may be patterned through any suitable process (e.g., photolithography and etch process). In some embodiments, one or more etch process(es) may be performed to form trenches extending through the first semiconductor layer 42, such that the semiconductor layers 42a and 42b are separated from each other. In the embodiment shown in FIGS. 1F and 1G, the Ohmic material layer 300 (the first device metal layer 30) is patterned through any suitable process (e.g., photolithography and etch process) to form a plurality of Ohmic contacts 30oa and 30ob. In some embodiments, the first conductive metal layer 50 may also be patterned through suitable process to form a first wiring layer 50′. The first wiring layer 50′ may comprise conductive features, for example, a plurality of conductive lines. However, the present disclosure is not limited thereto.

As shown in FIGS. 1F and 1G, a first dielectric structure 92 is formed. The first dielectric structure 92 may surround each of the semiconductor layer 42a, the semiconductor layer 42b, the Ohmic contact 300a, and the Ohmic contact 30ob. The first dielectric structure 92 may include one or more stacked dielectric layers. The first dielectric structure 92 may comprise dielectric material such as silicon oxide, silicon oxynitride, low dielectric constant (low k) materials, a combination thereof, and/or other applicable material and may be formed by deposition such as CVD, PVD, or ALD, spinning, or any suitable method. The first dielectric structure 92 may fill the trench between the semiconductor layer 42a and the semiconductor layer 42b and between the Ohmic contact 300a and the Ohmic contact 30ob, such that the semiconductor layer 42a and the semiconductor layer 42b are laterally isolated by the first dielectric structure 92, and the Ohmic contact 300a and the Ohmic contact 30ob are laterally isolated by the first dielectric structure 92.

As shown in FIGS. 1F and 1G, a second device metal layer 60 is formed (step (f)). In the present embodiment, the second device metal layer 60 comprises a plurality of Schottky contacts 60sa and 60sb. The Schottky contacts 60sa and 60sb (the second device metal layer 60) may be formed in contact with the respective semiconductor layers 42a and 42b. The Schottky contacts 60sa and 60sb may comprise suitable metal, alloy, or conductive metal compound, e.g., Pt, Pd, Ir, Ru, Cu, W, the like, or combinations thereof, such that a Schottky junction can be formed between the Schottky contacts 60sa and 60sb and the respective semiconductor layers 42a and 42b. In some embodiments, thicknesses of the Schottky contacts 60sa and 60sb may be in a range between 1 nm and 100 nm. These values are merely examples and are not intended to be limiting.

In some embodiments, a Schottky material layer 60s (shown in FIG. 1F) may be formed by deposition such as CVD, PVD, or ALD and then be patterned before the patterning the first semiconductor layer 42 through any suitable process (e.g., photolithography and etch process) to form a plurality of Schottky contacts 60sa and 60sb. In some embodiments, the Schottky contacts 60sa and 60sb may be formed in the first dielectric structure 92 using a damascene or dual damascene process after the patterning the first semiconductor layer 42.

Referring to FIG. 1G, Schottky diodes 201a and 201b are provided. The Schottky diode 201a comprises the Ohmic contact 300a, the semiconductor layer 42a, and the Schottky contact 60sa. As shown in FIG. 1G, the semiconductor layer 42a is disposed over the Ohmic contact 300a, and the Schottky contact 60sa is disposed over the semiconductor layer 42a. In other words, the Schottky diode 201a may be a “vertical diode”. In some embodiments, the semiconductor layer 42a comprises a single crystalline semiconductor material. The Schottky contact 60sa is disposed in contact with the semiconductor layer 42a at one end of the semiconductor layer 42a with a Schottky junction formed therebetween. The Ohmic contact 30oa is disposed in contact with the semiconductor layer 42a at an opposite end of the semiconductor layer 42a with an Ohmic junction formed therebetween. The semiconductor layer 42a may further comprise a heavily-doped region 44a. Both the semiconductor layer 42a and the heavily-doped region 44a are of the first conductivity type as described above. The Ohmic contact 300a may be in contact with the heavily-doped region 44a with an Ohmic junction formed therebetween.

The Schottky diode 201b comprises the Ohmic contact 30ob, the semiconductor layer 42b, and the Schottky contact 60sb. As shown in FIG. 1G, the semiconductor layer 42b is disposed over the Ohmic contact 30ob, and the Schottky contact 60sb is disposed over the semiconductor layer 42b. In other words, the Schottky diode 201b may be a “vertical diode”. In some embodiments, the semiconductor layer 42b comprises a single crystalline semiconductor material. The Schottky contact 60sb is disposed in contact with the semiconductor layer 42b at one end of the semiconductor layer 42b with a Schottky junction formed therebetween. The Ohmic contact 30ob is disposed in contact with the semiconductor layer 42b at an opposite end of the semiconductor layer 42b with an Ohmic junction formed therebetween. The semiconductor layer 42b may further comprise a heavily-doped region 44b. Both the semiconductor layer 42b and the heavily-doped region 44b are of the first conductivity type as described above. The Ohmic contact 30ob may be in contact with the heavily-doped region 44b with an Ohmic junction formed therebetween. The first dielectric structure 92 surrounds each of the Schottky diodes 201a and 201b.

By methods disclosed herein, vertical Schottky diode may be formed with both a Schottky contact and an Ohmic contact disposed in contact with the semiconductor layer at opposite ends of the semiconductor layer while having a semiconductor layer made of single crystalline semiconductor material. As such, Schottky diodes with smaller size (feature squares) and better electrical characteristics may be formed. Also, by using the process described herein, high-temperature annealing process(es) may be finished in the early stage, therefore, high-temperature process(es) at a later stage may be avoided.

As shown in FIG. 1H, memory units 70a and 70b may be formed (step (i)). In the present embodiment, the memory units 70a and 70b are formed after removing the portion of the second substrate 40 and after the formation and the patterning of the first semiconductor layer 42. The memory units 70a and 70b may each comprise a magnetic tunnel junction (MTJ) structure, a phase-change material, or a variable resistance material. In the embodiment shown in FIG. 1H, the memory units 70a and 70b may each comprise a phase-change material or a variable resistance material. In some embodiments, a second dielectric structure 94 substantially similar to the first dielectric structure 92 may be formed over the first dielectric structure 92, and the memory units 70a and 70b may be formed in the second dielectric structure 94.

As shown in FIG. 1H, a second conductive metal layer 80 is formed (step (f)). The second conductive metal layer 80 may be a second wiring layer comprising conductive features (e.g., conductive lines or vias). In the present embodiment, the second wiring layer 80 are formed after the formation and the patterning of the first semiconductor layer 42 and after the formation of the memory units 70a and 70b. The second wiring layer 80 may comprise copper, aluminum, tungsten, some other suitable material(s), or a combination of the foregoing and may be formed in the second dielectric structure 94 using a damascene or dual damascene process or any suitable method.

Referring to FIG. 1H, memory cells 301a and 301b are provided. The memory cell 301a comprises the Schottky diode 201a and the memory unit 70a. The memory unit 70a is electrically coupled to the Schottky contact 60sa from a first end of the memory unit 70a and electrically coupled to the second wiring layer 80 from a second end of the memory unit 70a. The memory cell 301b comprises the Schottky diode 201b and the memory unit 70b. The memory unit 70b is electrically coupled to the Schottky contact 60sb from a first end of the memory unit 70b and electrically coupled to the second wiring layer 80 from a second end of the memory unit 70b. The memory cells 301a and 301b shown in FIG. 1H may be PcRAM cells or RRAM cells, and the first wiring layer 50′ and the second wiring layer 80 may serve as bit lines and/or word lines for the memory cells. Despite that only two diodes and two memory cells are illustrated in FIGS. 1A to 1H, a plurality of diodes and memory cells or an array of diodes and memory cells can be fabricated at the same time using the method disclosed herein.

FIGS. 2A to 2E are schematic diagrams illustrating intermediate stages in the manufacture of a semiconductor structure according to one embodiment of the present disclosure.

As shown in FIG. 2A, a second structure 101B is provided (step (b)). The second structure 101B shown in FIG. 2A may be substantially similar to the second structure 100B described above with respect to FIG. 1B, where like reference numerals indicate like elements. In the present embodiment, the first device metal layer 30 comprises a plurality of Ohmic contacts 300a and 30ob. The Ohmic contacts 300a and 30ob may comprise material(s) similar to that of the Ohmic material layer 300 discussed above with respect to FIG. 1B. Specifically, in the embodiment shown in FIG. 2A, dielectric structure 91 substantially similar to the first dielectric structure 92 may be formed on the second substrate 40, and the Ohmic contacts 300a and 30ob may be formed in the dielectric structure 91 using a damascene or dual damascene process before bonding of a first structure and the second structure 101B. The Ohmic contacts 30oa and 30ob may be formed in contact with the first heavily-doped layer 44. In some embodiments, the thicknesses of the Ohmic contacts 300a and 30ob may be in a range between 2 nm and 100 nm. These values are merely examples and are not intended to be limiting.

As shown in FIG. 2A, a first conductive metal layer 50′ may be formed on the Ohmic contacts 300a and 30ob. The first conductive metal layer 50′ may be a first wiring layer comprising conductive features (e.g., conductive lines or vias) and may be electrically connected to the Ohmic contacts 300a and 30ob. The first wiring layer 50′ may comprise copper, aluminum, tungsten, some other suitable material(s), or a combination of the foregoing and may be formed in the dielectric structure 91 using a damascene or dual damascene process or any suitable method. In the present embodiment, the first wiring layer 50′ is formed before bonding of a first structure and the second structure 101B.

As shown in FIG. 2B, a first structure is provided (step (a)), wherein the first structure comprises a first substrate 10 similar to that described above with respect to FIG. 1C; and, the second structure 101B is flipped and bonded onto the first structure by a bonding layer 20 (step (c)). The bonding process and related details described before may apply here.

As shown in FIG. 2C, a portion of the second substrate 40 is removed from approximately the implanted hydrogen layer 41 to form a first semiconductor layer 42 (step (d)). The removal process and the related details described before may apply here.

As shown in FIG. 2D, the first semiconductor layer 42 is patterned to form a plurality of semiconductor layers 42a and 42b (step (e)), and a second device metal layer 60 is formed (step (f)). In the present embodiment, the second device metal layer 60 comprises a plurality of Schottky contacts 60sa and 60sb. The semiconductor structure shown in FIG. 2D may be formed by processes similar to that described above with respect to FIGS. 1F to 1G. Related details described above may apply here if applicable. As such, Schottky diodes 201a and 201b are provided. The Schottky diodes 201a and 201b may be similar to that described above with respect to FIG. 1G, where like reference numerals indicate like elements.

As shown in FIG. 2E, memory units 70a and 70b may be formed (step (i)). In the embodiment shown in FIG. 2E, the memory units 70a and 70b may each comprise a phase-change material or a variable resistance material. A second conductive metal layer 80 may also be formed (step (f)). Details and formation methods of the memory units 70a and 70b and the second conductive metal layer 80 may be similar to that described above with respect to FIG. 1H, and the related description is omitted for brevity. As such, memory cells 301a and 301b are provided. The memory cells 301a and 301b may be similar to that described above with respect to FIG. 1H, where like reference numerals indicate like elements.

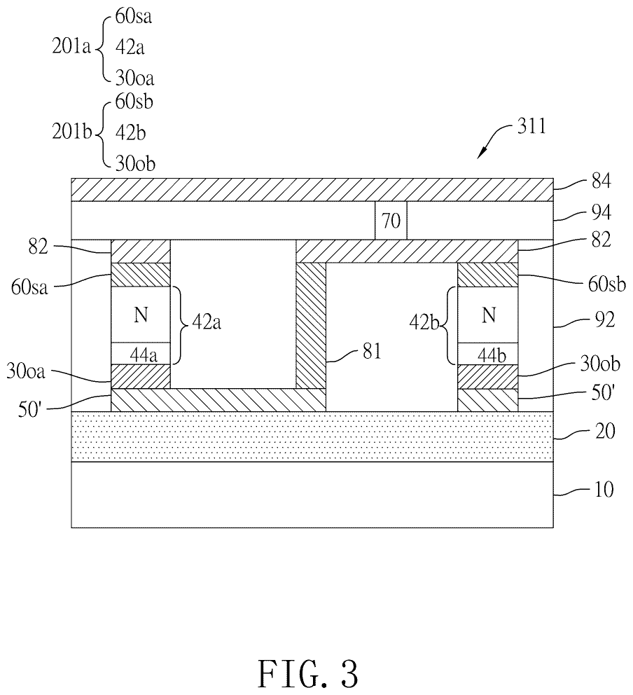

FIG. 3 is a schematic view to illustrate an embodiment of a memory device according to the present disclosure. As shown in FIG. 3, a memory cell 311 is provided. The memory cell 311 or similar semiconductor structures may be formed by processes similar to that described herein with respect to FIGS. 1A to 1H, 2A to 2E, 4A to 4F, and 5A to 5C.

Specifically, in the present embodiment, the memory cell 311 comprises Schottky diodes 201a and 201b and a memory unit 70. The Schottky diodes 201a and 201b may be similar to that described above with respect to FIGS. 1G and 2D, where like reference numerals indicate like elements. In the embodiment shown in FIG. 3, a conductive via 81 and a third wiring layer 82 may be formed, such that the Schottky contact 60sb of the Schottky diode 201b is electrically coupled to the Ohmic contact 300a of the Schottky diode 201a through conductive feature(s) of the third wiring layer 82, the conductive via 81, and conductive feature(s) of the first wiring layer 50′. The conductive via 81 and the third wiring layer 82 may be formed by similar material and formation methods as that of the second wiring layer 80 described above with respect to FIG. 1H. A second wiring layer 84 similar to the second wiring layer 80 shown in FIG. 1H may also be formed after the formation of the memory unit 70.

In the embodiment shown in FIG. 3, the memory unit 70 is electrically coupled to both the Ohmic contact 30oa of the Schottky diode 201a and the Schottky contact 60sb of the Schottky diode 201b from a first end of the memory unit 70 and electrically coupled to the second wiring layer 84 from a second end of the memory unit 70. The memory unit 70 may comprise a magnetic tunnel junction (MTJ) structure or a phase-change material. The MTJ structure may comprise a free magnetic layer, a fixed magnetic layer, and a tunnel barrier layer between the free magnetic layer and the fixed magnetic layer. The fixed magnetic layer may have a fixed magnetization and the free magnetic layer may have a magnetization switchable by a program current. The orientation of magnetization in the free magnetic layer relative to that of the fixed magnetic layer may determine whether the MTJ structure is in a high resistance state or a low resistance state (e.g., whether the memory unit is storing a “1” or a “0”). For example, if the magnetization of the free magnetic layer and the fixed magnetic layer are in a parallel orientation, the MTJ structure may be in a low resistance state (e.g., “0” state); and if the magnetization of the free magnetic layer and the fixed magnetic layer are in an oppositional (anti-parallel) orientation, the MTJ structure may be in a high resistance state (e.g., “1” state). Data writing can be performed by switching the orientation of the magnetization of the free magnetic layer. In some embodiments, to enhance the performance of the MTJ structure, the free magnetic layer and/or the fixed magnetic layer may include a multilayer structure. The MTJ structure may be formed by any suitable method and any material suitable for each layer thereof.

The memory cell 311 shown in FIG. 3 may be a spin-transfer torque type MRAM (STT-MRAM) cell, and the first wiring layer 50′, the second wiring layer 84, and the third wiring layer 82 may serve as bit lines and/or word lines for the memory cell. Despite that only two diodes and one memory cell is illustrated in FIG. 3, a plurality of diodes and memory cells or an array of diodes and memory cells can be fabricated at the same time using the method disclosed herein.

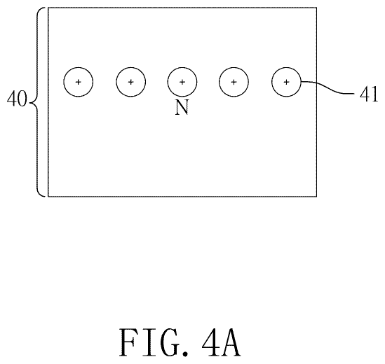

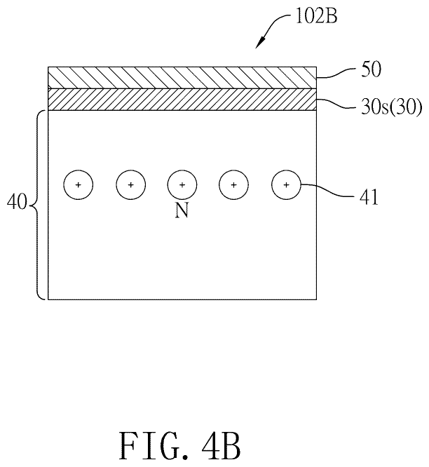

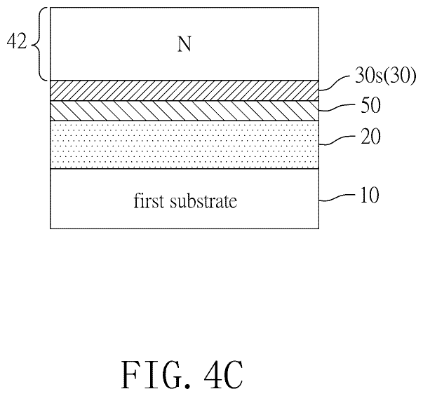

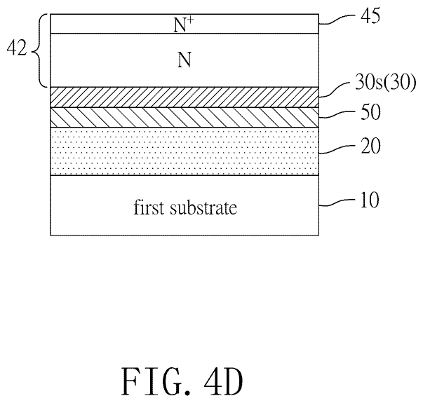

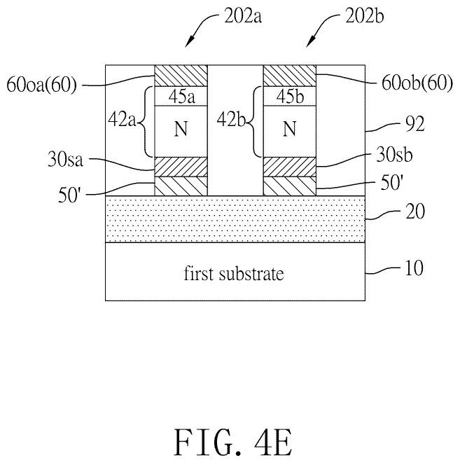

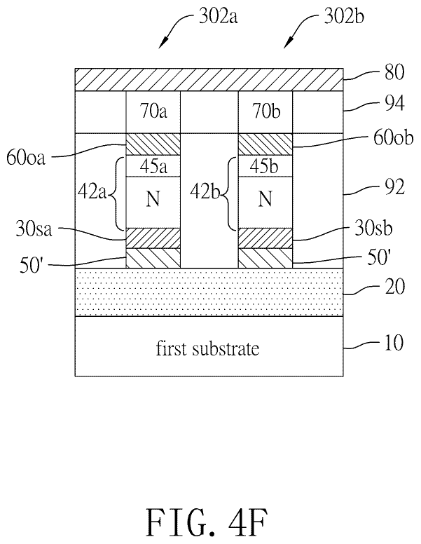

FIGS. 4A to 4F are schematic diagrams illustrating intermediate stages in the manufacture of a semiconductor structure according to one embodiment of the present disclosure.

As shown in FIG. 4A, a second substrate 40 is provided (step (b1)), and a hydrogen layer 41 may be implanted into the second substrate 40 (step (b2)). Related details with regard to the second substrate 40 and the implanted hydrogen layer 41 described before may apply here.

As shown in FIG. 4B, a first device metal layer 30 is formed on the second substrate 40 (step (b3)). The first device metal layer 30 may be formed in contact with the second substrate 40. In the embodiment shown in FIG. 4B, the first device metal layer 30 comprises a Schottky material layer 30s. The Schottky material layer 30s may comprise suitable metal, alloy, or conductive metal compound, e.g., Pt, Pd, Ir, Ru, Cu, W, or combinations thereof, such that a Schottky junction can be formed between the Schottky material layer 30s and the second substrate 40. The Schottky material layer 30s may be formed by deposition such as chemical vapor deposition (CVD), physical vapor deposition (PVD), or atomic layer deposition (ALD). In the embodiment shown in FIG. 4B, the Schottky material layer 30s is unpatterned. In some embodiments, the thickness of the Schottky material layer 30s may be in a range between 2 nm and 100 nm. These values are merely examples and are not intended to be limiting. In some other embodiments, the first device metal layer may comprise a plurality of Schottky contacts formed of similar material(s) as the Schottky material layer 30s. The Schottky contacts may be formed by methods similar to that of the Ohmic contacts 300a and 30ob described above with respect to FIG. 2A.

As shown in FIG. 4B, a first conductive metal layer 50 similar to that described above with respect to FIG. 1B may be formed on the first device metal layer 30. In the embodiment shown in FIG. 4B, the first conductive metal layer 50 comprises an unpatterned conductive metal material layer. However, in some other embodiments, the first conductive metal layer may comprise patterned conductive features and may be similar to the first wiring layer 50′ described above with respect to FIG. 2A. As such, a second structure 102B is provided (step (b)). The second structure 102B shown in FIG. 4B may be substantially similar to the second structure 100B described above with respect to FIG. 1B, where like reference numerals indicate like elements. In the present embodiment, the first device metal layer 30 comprises a Schottky material layer 30s.

As shown in FIG. 4C, a first structure is provided (step (a)), wherein the first structure comprises a first substrate 10 similar to that described above with respect to FIG. 1C; and, the second structure 102B is flipped and bonded onto the first structure by a bonding layer 20 (step (c)). The bonding process and related details described before may apply here.

Then, a portion of the second substrate 40 is removed from approximately the implanted hydrogen layer 41 to form a first semiconductor layer 42 (step (d)). The removal process and the related details described before may apply here.

As shown in FIG. 4D, a second heavily-doped layer 45 is formed (step (h)). In the embodiment shown in FIG. 4D, the second heavily-doped layer 45 is formed after removing a portion of the second substrate 40. In some embodiments, the second heavily-doped layer 45 is formed in the first semiconductor layer 42 extending from the top surface of the first semiconductor layer 42. In some embodiments, the second heavily-doped layer 45 is formed on and in contact with the top surface of the first semiconductor layer 42. The second heavily-doped layer 45 may be of the first conductivity type as described above. The second heavily-doped layer 45 may have a higher doping concentration than that of the first semiconductor layer 42. In some embodiments, the doping concentration of the second heavily-doped layer 45 may be from about 1.0×10¹⁸ atoms/cm³ to about 3.0×10²⁰ atoms/cm³. In some embodiments, the thickness of the second heavily-doped layer 45 may be in a range between 2 nm and 100 nm. These values are merely examples and are not intended to be limiting. In the embodiment shown in FIG. 4D, the second heavily-doped layer 45 is unpatterned. The second heavily-doped layer 45 may be formed by ion implantation or epitaxial growth.

As shown in FIG. 4E, the first semiconductor layer 42 is patterned to form a plurality of semiconductor layers 42a and 42b (step (e)), and a second device metal layer 60 is formed (step (f)). In the present embodiment, the second device metal layer 60 comprises a plurality of Ohmic contacts 60oa and 60ob. The semiconductor structure shown in FIG. 4E may be formed by processes similar to that described above with respect to FIGS. 1F to 1G. Related details described above may apply here if applicable.

Specifically, in the embodiment shown in FIG. 4E, the Schottky material layer 30s (the first device metal layer 30) may be patterned through any suitable process (e.g., photolithography and etch process) to form a plurality of Schottky contacts 30sa and 30sb. In some embodiments, the first conductive metal layer 50 may also be patterned through suitable process to form a first wiring layer 50′. The second heavily-doped layer 45 may be patterned to form a plurality of heavily-doped regions 45a and 45b, and the Ohmic contacts 600a and 60ob are formed in contact with the respective heavily-doped regions 45a and 45b. The formation methods of the Ohmic contacts 600a and 60ob may be similar to that of the Schottky contacts 60sa and 60sb described above with respect to FIGS. 1F to 1G.

Referring to FIG. 4E, Schottky diodes 202a and 202b are provided. The Schottky diode 202a comprises the Schottky contact 30sa, the semiconductor layer 42a, and the Ohmic contact 600a. As shown in FIG. 4E, the semiconductor layer 42a is disposed over the Schottky contact 30sa, and the Ohmic contact 600a is disposed over the semiconductor layer 42a. In other words, the Schottky diode 202a may be a “vertical diode”. In some embodiments, the semiconductor layer 42a comprises a single crystalline semiconductor material. The Schottky contact 30sa is disposed in contact with the semiconductor layer 42a at one end of the semiconductor layer 42a with a Schottky junction formed therebetween. The Ohmic contact 60oa is disposed at an opposite end of the semiconductor layer 42a. The Ohmic contact 600a may be in contact with the heavily-doped region 45a with an Ohmic junction formed therebetween. Both the semiconductor layer 42a and the heavily-doped region 45a are of the first conductivity type as described above.

The Schottky diode 202b comprises the Schottky contact 30sb, the semiconductor layer 42b, and the Ohmic contact 60ob. As shown in FIG. 1G, the semiconductor layer 42b is disposed over the Schottky contact 30sb, and the Ohmic contact 60ob is disposed over the semiconductor layer 42b. In other words, the Schottky diode 202b may be a “vertical diode”. In some embodiments, the semiconductor layer 42b comprises a single crystalline semiconductor material. The Schottky contact 30sb is disposed in contact with the semiconductor layer 42b at one end of the semiconductor layer 42b with a Schottky junction formed therebetween. The Ohmic contact 60ob is disposed at an opposite end of the semiconductor layer 42b. The Ohmic contact 60ob may be in contact with the heavily-doped region 45b with an Ohmic junction formed therebetween. Both the semiconductor layer 42b and the heavily-doped region 45b are of the first conductivity type as described above. A first dielectric structure 92 similar to that described above with respect to FIGS. 1F and 1G surrounds each of the Schottky diodes 202a and 202b. As such, Schottky diodes with smaller size (feature squares) and better electrical characteristics may be formed.

As shown in FIG. 4F, memory units 70a and 70b may be formed (step (i)). In the embodiment shown in FIG. 4F, the memory units 70a and 70b may each comprise a phase-change material or a variable resistance material. A second conductive metal layer 80 may also be formed (step (f)). Details and formation methods of the memory units 70a and 70b and the second conductive metal layer 80 may be similar to that described above with respect to FIG. 1H, and the related description is omitted for brevity.

Referring to FIG. 4F, memory cells 302a and 302b are provided. The memory cell 302a comprises the Schottky diode 202a and the memory unit 70a. The memory unit 70a is electrically coupled to the Ohmic contact 600a of the Schottky diode 202a from a first end of the memory unit 70a and electrically coupled to the second wiring layer 80 from a second end of the memory unit 70a. The memory cell 302b comprises the Schottky diode 202b and the memory unit 70b. The memory unit 70b is electrically coupled to the Ohmic contact 60ob the Schottky diode 202b from a first end of the memory unit 70b and electrically coupled to the second wiring layer 80 from a second end of the memory unit 70b. The memory cells 302a and 302b shown in FIG. 4F may be PcRAM cells or RRAM cells, and the first wiring layer 50′ and the second wiring layer 80 may serve as bit lines and/or word lines for the memory cells. Despite that only two diodes and two memory cells are illustrated in FIGS. 4A to 4F, a plurality of diodes and memory cells or an array of diodes and memory cells can be fabricated at the same time using the method disclosed herein.

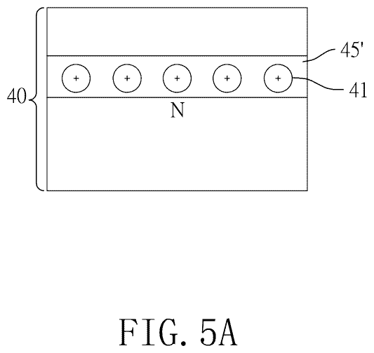

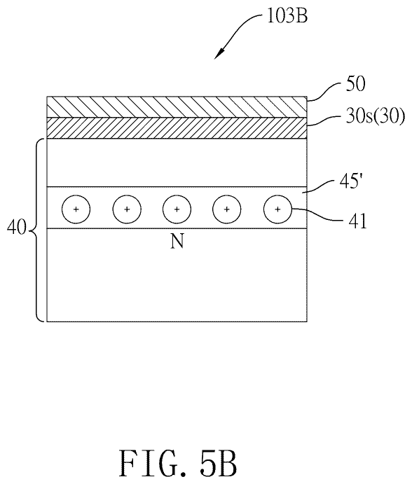

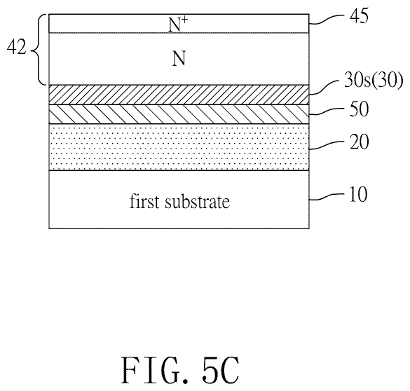

FIGS. 5A to 5C are schematic diagrams illustrating intermediate stages in the manufacture of a semiconductor structure according to one embodiment of the present disclosure.

As shown in FIG. 5A, a second substrate 40 is provided (step (b1)), and a hydrogen layer 41 may be implanted into the second substrate 40 (step (b2)). In the present embodiment, a second heavily-doped layer 45′ may be formed at a desired depth from the top surface of the second substrate 40, e.g., by ion implantation. The second heavily-doped layer 45′ is formed before bonding of a first structure and a second structure. The second heavily-doped layer 45′ may be of the first conductivity type as described above. The second heavily-doped layer 45′ may have a higher doping concentration than that of the second substrate 40. In some embodiments, the doping concentration of the second heavily-doped layer 45′ may be from about 1.0×10¹⁸ atoms/cm³ to about 3.0×10²⁰ atoms/cm³. These values are merely examples and are not intended to be limiting. Related details with regard to the second substrate 40 and the implanted hydrogen layer 41 described before may apply here if applicable. In some embodiments, the second heavily-doped layer 45′ may be formed before the implantation of the hydrogen layer 41.

As shown in FIG. 5B, a second structure 103B is provided (step (b)). The second structure 103B shown in FIG. 5B may be substantially similar to the second structure 102B described above with respect to FIG. 4B, where like reference numerals indicate like elements. In the present embodiment, the second substrate 40 further comprises a second heavily-doped layer 45′.

As shown in FIG. 5C, a first structure is provided (step (a)), wherein the first structure comprises a first substrate 10 similar to that described above with respect to FIG. 1C; and, the second structure 103B is flipped and bonded onto the first structure by a bonding layer 20 (step (c)). The bonding process and related details described before may apply here.

Then, a portion of the second substrate 40 is removed from approximately the implanted hydrogen layer 41 to form a first semiconductor layer 42 (step (d)). The removal process and the related details described before may apply here. In the present embodiment, the second heavily-doped layer 45 is exposed after removing a portion of the second substrate 40 and planarization of the exposed surface. Semiconductor structures similar to the Schottky diodes 202a and 202b and the memory cells 302a and 302b in FIGS. 4E and 4F may be formed from the structure shown in FIG. 5C by process(es) similar to that described above with respect to FIGS. 4E to 4F.

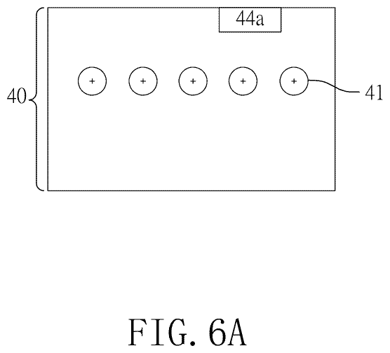

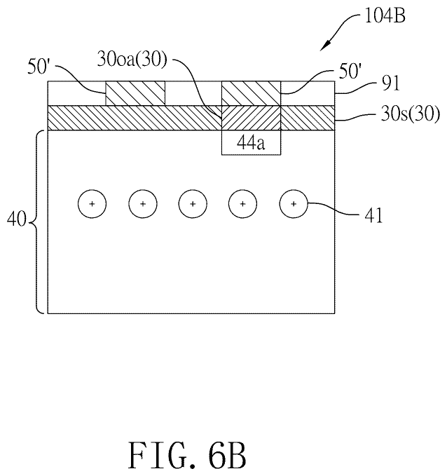

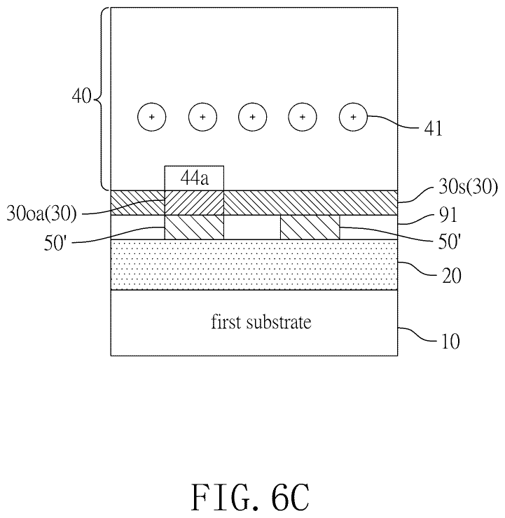

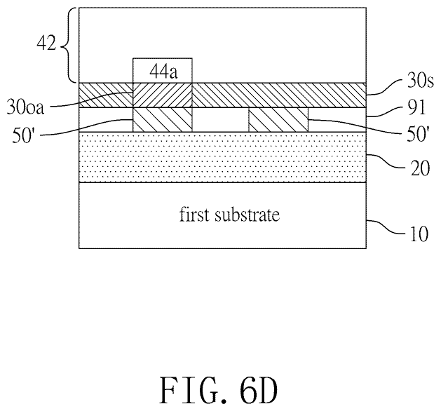

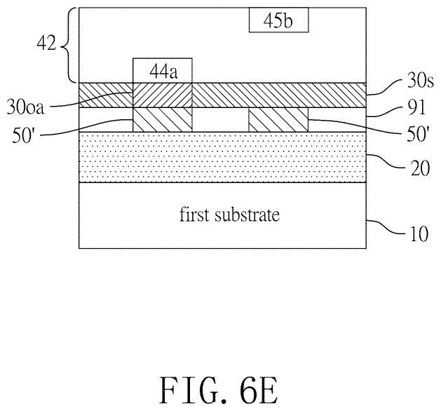

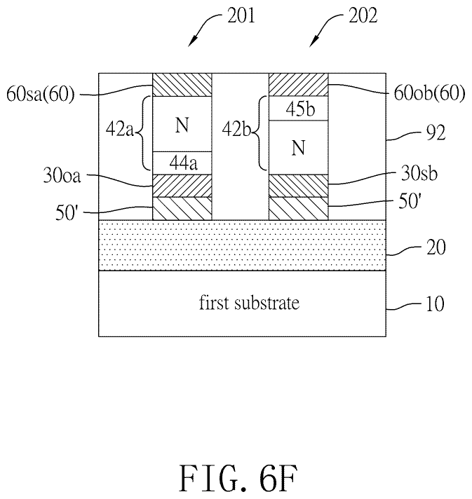

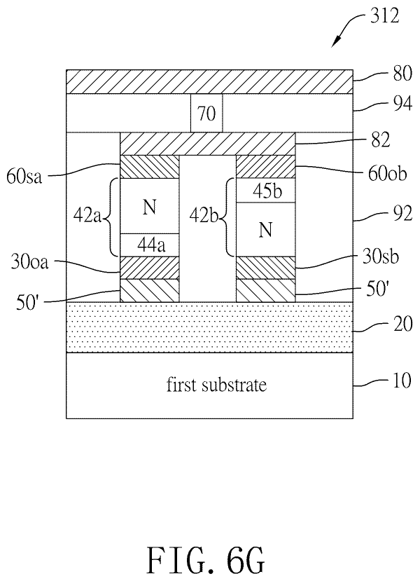

FIGS. 6A to 6G are schematic diagrams illustrating intermediate stages in the manufacture of a semiconductor structure according to one embodiment of the present disclosure.

As shown in FIG. 6A, a second substrate 40 is provided (step (b1)), and a hydrogen layer 41 may be implanted into the second substrate 40 (step (b2)). In the present embodiment, the second substrate 40 comprises a patterned first heavily-doped layer including a heavily-doped region 44a extending from a top surface of the second substrate 40. The heavily-doped region 44a may be formed by ion implantation or epitaxial growth. The heavily-doped region 44a is of the first conductivity type as described above. The heavily-doped region 44a may have a higher doping concentration than that of the second substrate 40. In some embodiments, the doping concentration of the heavily-doped region 44a may be from about 1.0×10¹⁸ atoms/cm³ to about 3.0×10²⁰ atoms/cm³. In one embodiment, the thickness of the heavily-doped region 44a may be in a range between 2 nm and 100 nm. These values are merely examples and are not intended to be limiting. Related details with regard to the second substrate 40 and the implanted hydrogen layer 41 described before may apply here if applicable.

As shown in FIG. 6B, a second structure 104B is provided (step (b)). The second structure 104B shown in FIG. 6B may be substantially similar to the second structure 101B described above with respect to FIG. 2A, where like reference numerals indicate like elements. In the present embodiment, the first device metal layer 30 comprises a patterned Schottky material layer 30s and an Ohmic contact 300a. The Ohmic contact 300a may be similar to that described above with respect to FIG. 2A. The patterned Schottky material layer 30s may be substantially similar to the Schottky material layer 30s described above with respect to FIG. 4B.

The patterned Schottky material layer 30s may be formed by deposition such as chemical vapor deposition (CVD), physical vapor deposition (PVD), or atomic layer deposition (ALD). In some embodiments, an unpatterned Schottky material layer (not shown) may be formed on the second substrate 40 and then be patterned through any suitable process (e.g., photolithography and etch process) to form the patterned Schottky material layer 30s. In some embodiments, trench(es) can be etched through the unpatterned Schottky material layer, and the Ohmic contacts 300a may be formed in the trench(es). The Ohmic contact 300a may be formed in contact with the heavily-doped region 44a. In some embodiments, the Ohmic contact 30oa may be formed by similar methods described above with respect to FIG. 2A. In some embodiments, the thicknesses of the patterned Schottky material layer 30s and the Ohmic contact 300a may be in a range between 2 nm and 100 nm. These values are merely examples and are not intended to be limiting.

In some other embodiments, the first device metal layer may comprise a patterned Ohmic material layer and a Schottky contact and may be formed by similar method described herein. The patterned Ohmic material layer may be similar to the Ohmic material layer 300 described above with respect to FIG. 1B. The Schottky contact may be similar to that discussed above with respect to FIG. 4B. In yet some other embodiments, the first device metal layer may comprise an Ohmic contact and a Schottky contact and may be formed by similar method described above with respect to FIG. 2A. In yet some other embodiments, the first device metal layer may comprise a patterned Ohmic material layer and a patterned Schottky material layer and may be formed by similar method described herein.

As shown in FIG. 6C, a first structure is provided (step (a)), wherein the first structure comprises a first substrate 10 similar to that described above with respect to FIG. 1C; and, the second structure 104B is flipped and bonded onto the first structure by a bonding layer 20 (step (c)). The bonding process and related details described before may apply here.

As shown in FIG. 6D, a portion of the second substrate 40 is removed from approximately the implanted hydrogen layer 41 to form a first semiconductor layer 42 (step (d)). The removal process and the related details described before may apply here.

As shown in FIG. 6E, a second heavily-doped layer is formed (step (h)). In the present embodiment, the second heavily-doped layer is a patterned layer including a heavily-doped region 45b. In some embodiments, the doping concentration of the heavily-doped layer 45b may be from about 1.0×10¹⁸ atoms/cm³ to about 3.0×10²⁰ atoms/cm³. In some embodiments, the thickness of the heavily-doped layer 45b may be in a range between 2 nm and 100 nm. These values are merely examples and are not intended to be limiting. Details and formation methods of the second heavily-doped layer scribed before may apply here if applicable.

As shown in FIG. 6F, the first semiconductor layer 42 is patterned to form a plurality of semiconductor layers 42a and 42b (step (e)), and a second device metal layer 60 is formed (step (f)). In the present embodiment, the second device metal layer 60 comprises the second device metal layer 60 comprises both a Schottky contact 60sa and an Ohmic contact 60ob. The semiconductor structure shown in FIG. 6F may be formed by processes similar to that described above with respect to FIGS. 1F to 1G. Related details described above may apply here if applicable.

Specifically, in the embodiment shown in FIG. 6F, the Schottky material layer 30s may be further patterned through any suitable process (e.g., photolithography and etch process) to form a Schottky contact 30sb. As shown in FIG. 6F, the Ohmic contact 60ob is formed in contact with the heavily-doped region 45b.

Referring to FIG. 6F, Schottky diodes 201 and 202 are provided. The Schottky diode 201 shown in FIG. 6F may be substantially similar to the Schottky diodes 201a and 201b described above with respect to FIGS. 1G and 2D, where like reference numerals indicate like elements. The Schottky diode 202 shown in FIG. 6F may be substantially similar to the Schottky diodes 202a and 202b described above with respect to FIG. 4E, where like reference numerals indicate like elements. Related details described above may apply here if applicable.

In the present embodiment, the vertical Schottky diodes 201 and 202, which are manufactured under the same set of processes, are formed to be arranged in opposite directions. Such configuration may render a simplified routing and a reduced thickness of the overall semiconductor device.

As shown in FIG. 6G, a memory unit 70 may be formed (step (i)). The memory unit 70 may be similar to that discussed above with respect to FIG. 3.

In the embodiment shown in FIG. 6G, a third wiring layer 82 may be formed, such that the Schottky contact 60sa of the Schottky diode 201 is electrically coupled to the Ohmic contact 60ob of the Schottky diode 202 through conductive feature(s) of the third wiring layer 82. The third wiring layer 82 may be formed by similar material and formation methods as that of the second wiring layer 80 described above with respect to FIG. 1H. A second wiring layer 84 similar to the second wiring layer 80 shown in FIG. 1H may also be formed after the formation of the memory unit 70.

Referring to FIG. 6G, a memory cell 312 is provided. The memory cell 312 comprises Schottky diodes 201 and 202 and a memory unit 70. The memory unit 70 is electrically coupled to both the Schottky contact 60sa of the Schottky diode 201 and the Ohmic contact 60ob of the Schottky diode 202 from a first end of the memory unit 70 and electrically coupled to the second wiring layer 84 from a second end of the memory unit 70. The memory cell 312 shown in FIG. 6G may be a spin-transfer torque type MRAM (STT-MRAM) cell, and the first wiring layer 50′ and the second wiring layer 84 may serve as bit lines and/or word lines for the memory cell. Despite that only two diodes and one memory cell is illustrated in FIG. 6G, a plurality of diodes and memory cells or an array of diodes and memory cells can be fabricated at the same time using the method disclosed herein.

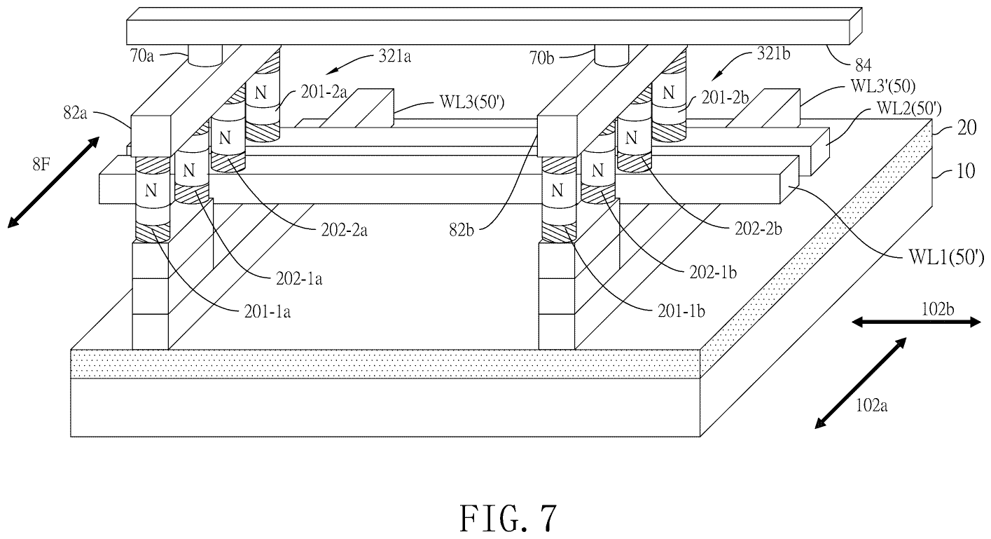

FIG. 7 is a schematic view to illustrate an embodiment of a memory device according to the present disclosure. As shown in FIG. 7, memory cells 321a and 321b are provided. The memory cells 321a and 321b or similar semiconductor structures may be formed by processes similar to that described herein with respect to FIGS. 6A to 6G.

Specifically, in the present embodiment, the memory cell 321a comprises a first pair of Schottky diodes 201-1a and 202-1a, a second pair of Schottky diodes 201-2a and 202-2a, an electrode 82a, and a memory unit 70a; the memory cell 321b comprises a first pair of Schottky diodes 201-1b and 202-1b, a second pair of Schottky diodes 201-2b and 202-2b, an electrode 82b, and a memory unit 70b. The Schottky diodes 201-1a, 202-1a, 201-2a, and 202-2a of the memory cell 321a and the Schottky diodes 201-1b, 202-1b, 201-2b, and 202-2b of the memory cell 321b may be disposed over a first wiring layer 50′. The memory unit 70a may be disposed over the Schottky diodes 201-1a, 202-1a, 201-2a, and 202-2a; and the memory unit 70b may be disposed over the Schottky diodes 201-1b, 202-1b, 201-2b, and 202-2b. A second wiring layer 84 may be disposed over the memory units 70a and 70a.

The Schottky diodes 201-1a, 201-2a, 201-1b, and 201-2b may be substantially similar to the Schottky diodes 201a and 201b described above with respect to FIGS. 1G and 2D; the Schottky diodes 202-1a, 202-2a, 202-1b, and 202-2b may be substantially similar to the Schottky diodes 202a and 202b described above with respect to FIG. 4E, where like reference numerals indicate like elements. As shown in FIG. 7, each of the first pair of Schottky diodes 201-1a and 202-1a and the second pair of Schottky diodes 201-2a and 202-2a of the memory cell 321a includes a diode pair that are arranged in opposite directions; and each of the first pair of Schottky diodes 201-1b and 202-1b and the second pair of Schottky diodes 201-2b and 202-2b of the memory cell 321b includes a diode pair that are arranged in opposite directions.

As shown in FIG. 7, the electrode 82a extends laterally in a first direction 102a. In some embodiments, the electrode 82a comprises materials with high spin Hall effect, for example, β-Tantalum (β-Ta), β-Tungsten (β-W), Ta, W, Pt, Cu doped with elements such as Ir, Bi, and any of the elements which may exhibit high spin-orbit coupling. The electrode 82a may be formed using a damascene or dual damascene process or any suitable method. The memory cell 321b may be similar to the memory cell 321a, where like reference numerals indicate like elements.

Referring to FIG. 7, both the Schottky diodes 201-1a and 202-1a are electrically coupled to the electrode 82a at a first side of the memory unit 70a, and both the Schottky diodes 201-2a and 202-2a are electrically coupled to the electrode 82a at a second side of the memory unit 70a. Similarly, both the Schottky diodes 201-1b and 202-1b are electrically coupled to the electrode 82b at a first side of the memory unit 70b, and both the Schottky diodes 201-2b and 202-2b are electrically coupled to the electrode 82b at a second side of the memory unit 70b.

The memory units 70a and 70b may comprise a magnetic tunnel junction (MTJ) structure. Details and formation methods of the memory unit 70a and 70b may be substantially similar to those described above with respect to FIG. 3, and the related description is omitted for brevity. The memory unit 70a may be electrically coupled to the electrode 82a at a first end of the memory unit 70a and may be electrically coupled to the second wiring layer 84 at a second end of the memory unit 70a. The memory unit 70b may be electrically coupled to the electrode 82b at a first end of the memory unit 70b and may be electrically coupled to the second wiring layer 84 at a second end of the memory unit 70b.

Each of the memory cells 321a and 321b shown in FIG. 7 may be a spin-orbit torque type MRAM (SOT-MRAM) cell, and the first wiring layer 50′ and the second wiring layer 84 may serve as bit lines and/or word lines for the memory cells. As shown in FIG. 7, each of the memory cells 321a and 321b may have a cell dimension of 8F and 2F respectively in the first direction 102a and the second direction 102b, which provides a cell size of 16 feature squares (F²). The symbol “F” herein denotes the minimum feature size (or one half of the minimum feature pitch) normally associated with a particular lithography process. Despite that only two memory cells are illustrated in FIG. 7, a plurality of memory cells or an array of cells can be fabricated at the same time using the method disclosed herein.

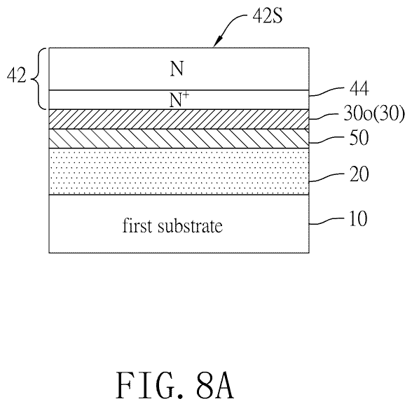

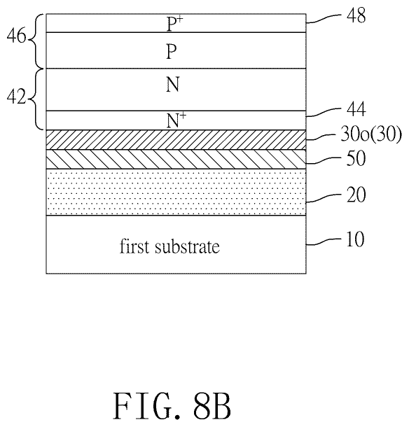

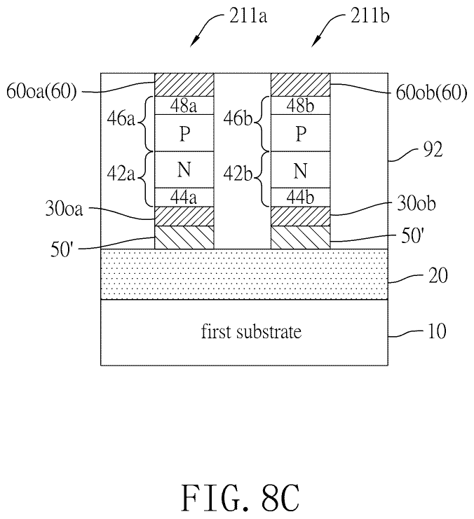

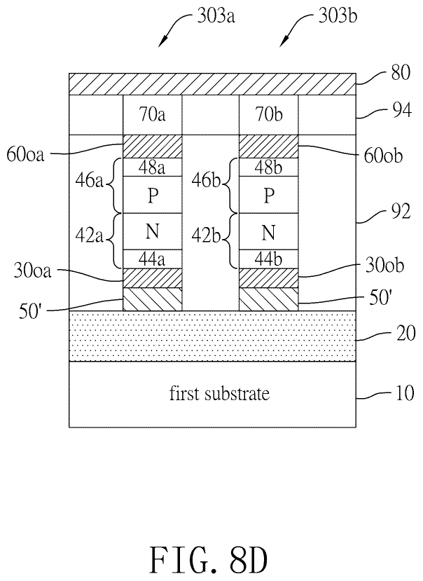

FIGS. 8A to 8D are schematic diagrams illustrating intermediate stages in the manufacture of a semiconductor structure according to one embodiment of the present disclosure.

As shown in FIG. 8A, a second structure comprising a second substrate and a first device metal layer 30 (an Ohmic material layer 300) is bonded to a first structure comprising a first substrate 10 by a bonding layer 20. Then, a portion of a second substrate is removed and a first semiconductor layer 42 is formed. Details and formation methods of the semiconductor structure shown in FIG. 8A may be substantially similar to that described above with respect to FIGS. 1A to 1E, and related description are omitted for brevity.

As shown in FIG. 8B, a second semiconductor layer 46 is formed on an exposed surface 42S of the first semiconductor layer 42 after removing a portion of the second substrate (step (j1)). In the embodiment shown in FIG. 8B, the second semiconductor layer 46 is of a second conductivity type (e.g., p-type) opposite the first conductivity type (e.g., n-type). However, the present disclosure is not limited thereto. In some embodiments, the second semiconductor layer 46 is formed on the first semiconductor layer 42 through epitaxial growth. In some embodiments, the second semiconductor layer 46 may be formed in the first semiconductor layer 42 shown in FIG. 8A by ion implantation or epitaxial growth. The second semiconductor layer 46 may further comprise a heavily-doped layer 48, wherein the heavily-doped layer 48 is of the second conductivity type. The heavily-doped layer 48 may have a higher doping concentration than that of the second semiconductor layer 46.

As shown in FIG. 8C, the first semiconductor layer 42 is patterned to form a plurality of semiconductor layers 42a and 42b (step (e)). The first heavily-doped layer 44 may also be patterned to form a plurality of heavily-doped regions 44a and 44b. In the embodiment shown in FIG. 8C, the step (e) further comprising patterning the second semiconductor layer 46. The second semiconductor layer 46 is patterned to form a plurality of semiconductor layers 46a and 46b. The heavily-doped layer 48 may also be patterned to form a plurality of heavily-doped regions 48a and 48b. In the embodiment shown in FIG. 8C, a plurality of Ohmic contacts 30oa and 30ob and a first wiring layer 50′ may also be formed. The patterning process and related details described before may apply here.

As shown in FIG. 8C, a second device metal layer 60 is formed (step (f)). In the present embodiment, the second device metal layer 60 comprises a plurality of Ohmic contacts 600a and 60ob. The Ohmic contacts 600a and 60ob (the second device metal layer 60) may be formed in contact with respective semiconductor layers 46a and 46b. The semiconductor structure shown in FIG. 8C may be formed by processes similar to that described above with respect to FIGS. 1F to 1G. Related details described above may apply here if applicable.

Referring to FIG. 8C, diodes 211a and 211b are provided. The diode 211a comprises the Ohmic contact 300a, the semiconductor layer 42a, the semiconductor layer 46a, and the Ohmic contact 600a. As shown in FIG. 8C, the semiconductor layer 42a is disposed over the Ohmic contact 300a, the semiconductor layer 46a is disposed over the semiconductor layer 42a, and the Ohmic contact 600a is disposed over the semiconductor layer 46a. In other words, the diode 211a may be a “vertical diode”. In some embodiments, the semiconductor layer 42a comprises a single crystalline semiconductor material. In some embodiments, the semiconductor layer 46a comprises a single crystalline semiconductor material. The Ohmic contact 600a may be disposed in contact with the semiconductor layer 46a with an Ohmic junction formed therebetween. The Ohmic contact 300a may be disposed in contact with the semiconductor layer 42a with an Ohmic junction formed therebetween. The semiconductor layer 42a is of the first conductivity type, and the semiconductor layer 46a is of the second conductivity type opposite the first conductivity type. The semiconductor layer 42a may be disposed in contact with the semiconductor layer 46a with a PN junction formed therebetween.

The diode 211b comprises the Ohmic contact 30ob, the semiconductor layer 42b, the semiconductor layer 46b, and the Ohmic contact 60ob. As shown in FIG. 8C, the semiconductor layer 42b is disposed over the Ohmic contact 30ob, the semiconductor layer 46b is disposed over the semiconductor layer 42b, and the Ohmic contact 60ob is disposed over the semiconductor layer 46b. In other words, the diode 211b may be a “vertical diode”. In some embodiments, the semiconductor layer 42b comprises a single crystalline semiconductor material. In some embodiments, the semiconductor layer 46b comprises a single crystalline semiconductor material. The Ohmic contact 60ob may be disposed in contact with the semiconductor layer 46b with an Ohmic junction formed therebetween. The Ohmic contact 30ob may be disposed in contact with the semiconductor layer 42b with an Ohmic junction formed therebetween. The semiconductor layer 42b is of the first conductivity type, and the semiconductor layer 46b is of the second conductivity type opposite the first conductivity type. The semiconductor layer 42b may be disposed in contact with the semiconductor layer 46b with a PN junction formed therebetween.

As shown in FIG. 8D, memory units 70a and 70b may be formed (step (i)). In the embodiment shown in FIG. 8D, the memory units 70a and 70b may each comprise a phase-change material or a variable resistance material. A second conductive metal layer 80 may also be formed (step (f)). Details and formation methods of the memory units 70a and 70b and the second conductive metal layer 80 may be similar to that described above with respect to FIG. 1H, and the related description is omitted for brevity.

Referring to FIG. 8D, memory cells 303a and 303b are provided. The memory cell 303a comprises the diode 211a and the memory unit 70a. The memory unit 70a is electrically coupled to the Ohmic contact 600a from a first end of the memory unit 70a and electrically coupled to the second wiring layer 80 from a second end of the memory unit 70a. The memory cell 303b comprises the diode 211b and the memory unit 70b. The memory unit 70b is electrically coupled to the Ohmic contact 60ob from a first end of the memory unit 70a and electrically coupled to the second wiring layer 80 from a second end of the memory unit 70b. The memory cells 303a and 303b shown in FIG. 8D may be PcRAM cells or RRAM cells, and the first wiring layer 50′ and the second wiring layer 80 may serve as bit lines and/or word lines for the memory cells. Despite that only two diodes and two memory cells are illustrated in FIGS. 8A to 8D, a plurality of diodes and memory cells or an array of diodes and memory cells can be fabricated at the same time using the method disclosed herein.

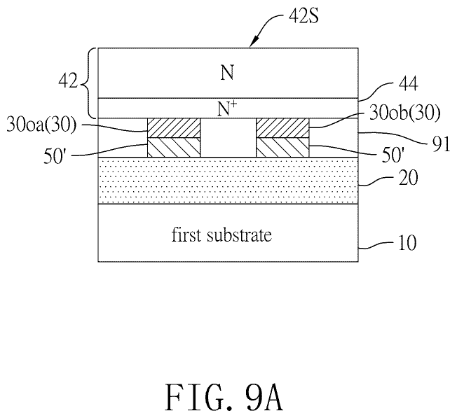

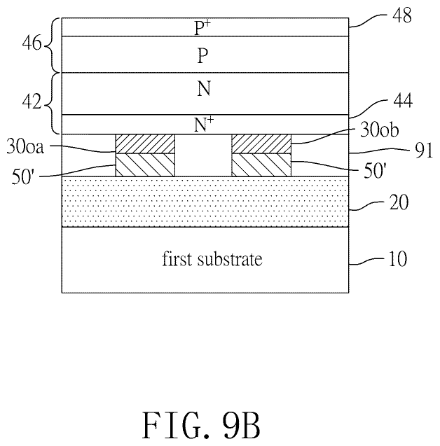

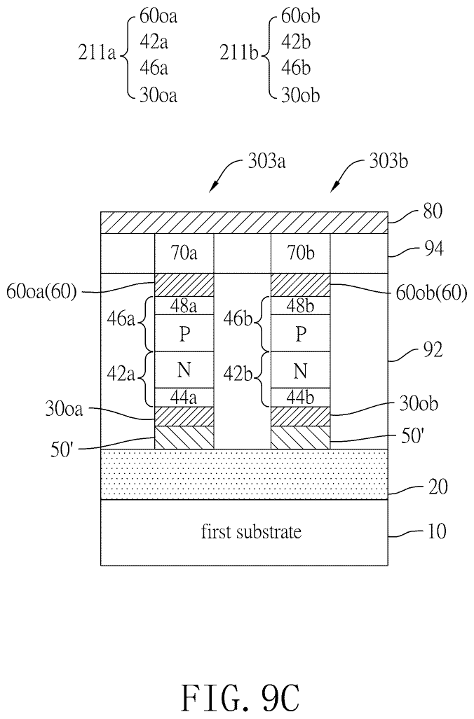

FIGS. 9A to 9C are schematic diagrams illustrating intermediate stages in the manufacture of a semiconductor structure according to one embodiment of the present disclosure.

As shown in FIG. 9A, a second structure comprising a second substrate and a first device metal layer 30 (Ohmic contacts 300a and 30ob) is bonded to a first structure comprising a first substrate 10 by a bonding layer 20. Then, a portion of a second substrate is removed and a first semiconductor layer 42 is formed. Details and formation methods of the semiconductor structure shown in FIG. 9A may be substantially similar to that described above with respect to FIGS. 2A to 2C, and related description are omitted for brevity.

As shown in FIG. 9B, a second semiconductor layer 46 is formed on an exposed surface 42S of the first semiconductor layer 42 after removing a portion of the second substrate (step (j1)). Details and formation methods of the second semiconductor layer 46 shown in FIG. 9B may be substantially similar to that described above with respect to FIG. 8B, and related description are omitted for brevity.

As shown in FIG. 9C, the first semiconductor layer 42 is patterned to form a plurality of semiconductor layers 42a and 42b (step (e)). The second semiconductor layer 46 is patterned to form a plurality of semiconductor layers 46a and 46b. A second device metal layer 60 is formed (step (f)). In the present embodiment, the second device metal layer 60 comprises a plurality of Ohmic contacts 600a and 60ob. The semiconductor structure shown in FIG. 9C may be formed by processes similar to that described above with respect to FIG. 8C. Related details described above may apply here if applicable. As such, diodes 211a and 211b are provided. The diodes 211a and 211b may be similar to that described above with respect to FIG. 8C, where like reference numerals indicate like elements.

As shown in FIG. 9C, memory units 70a and 70b may be formed (step (i)). In the present embodiment, the memory units 70a and 70b may each comprise a phase-change material or a variable resistance material. A second conductive metal layer 80 may also be formed (step (f)). Details and formation methods of the memory units 70a and 70b and the second conductive metal layer 80 may be similar to that described above with respect to FIG. 1H, and the related description is omitted for brevity. As such, memory cells 303a and 303b are provided. The memory cells 303a and 303b may be similar to that described above with respect to FIG. 8D, where like reference numerals indicate like elements.

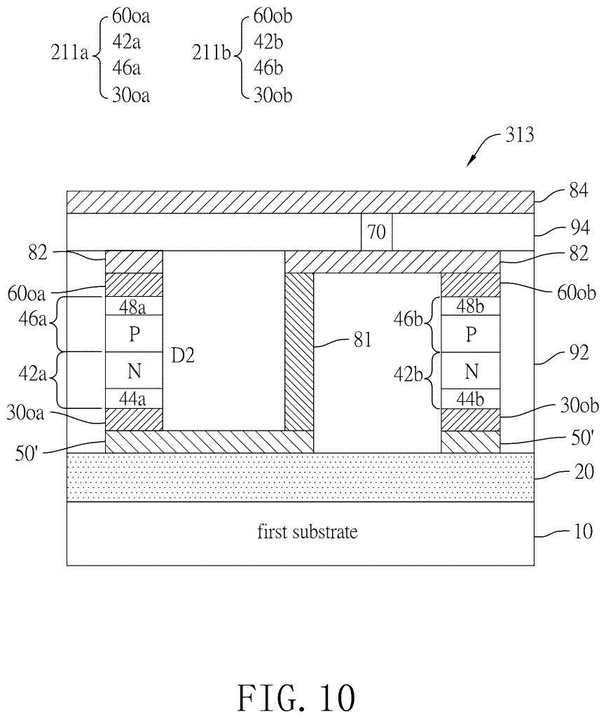

FIG. 10 is a schematic view to illustrate an embodiment of a memory device according to the present disclosure.

As shown in FIG. 10, a memory cell 313 is provided. The memory cell 313 or similar semiconductor structures may be formed by processes similar to that described herein with respect to FIGS. 8A to 8D, 9A to 9C, 11A to 11E, and 12A to 12C. The memory cell 313 shown in FIG. 10 may be substantially similar to the memory cell 311 described above with respect to FIG. 3, where like reference numerals indicate like elements.

In the embodiment shown in FIG. 10, the memory cell 313 comprises diodes 211a and 211b and a memory unit 70. The diodes 211a and 211b may be similar to that described above with respect to FIGS. 8C and 9C, where like reference numerals indicate like elements. In the embodiment shown in FIG. 10, a conductive via 81 and a third wiring layer 82 may be formed, such that the Ohmic contact 60ob of the diode 211b is electrically coupled to the Ohmic contact 300a of the diode 211a through conductive feature(s) of the third wiring layer 82, the conductive via 81, and conductive feature(s) of the first wiring layer 50′. In the embodiment shown in FIG. 10, the memory unit 70 is electrically coupled to both the Ohmic contact 300a of the diode 211a and the Ohmic contact 60ob of the diode 211b from a first end of the memory unit 70 and electrically coupled to the second wiring layer 84 from a second end of the memory unit 70.

The memory cell 313 shown in FIG. 10 may be a STT-MRAM cell, and the first wiring layer 50′, the second wiring layer 84, and the third wiring layer 82 may serve as bit lines and/or word lines for the memory cell. Despite that only two diodes and one memory cell is illustrated in FIG. 10, a plurality of diodes and memory cells or an array of diodes and memory cells can be fabricated at the same time using the method disclosed herein.

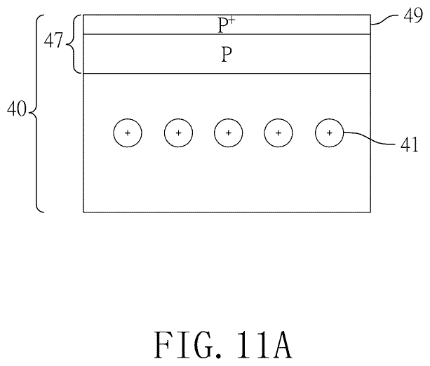

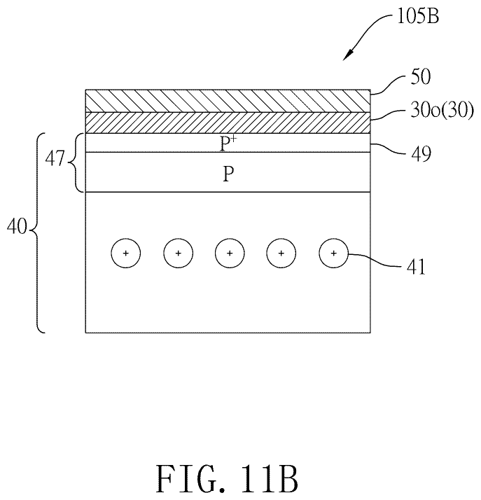

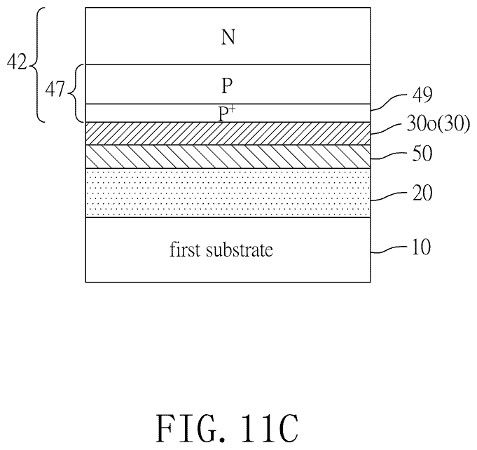

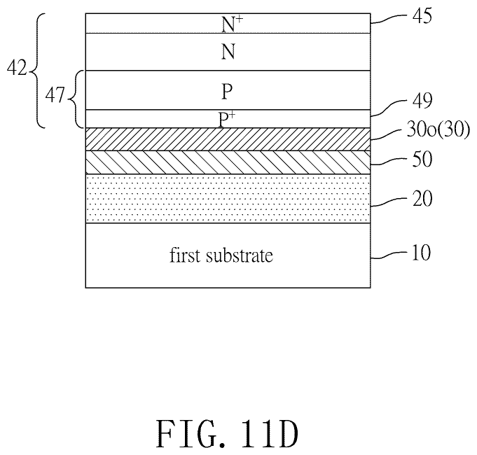

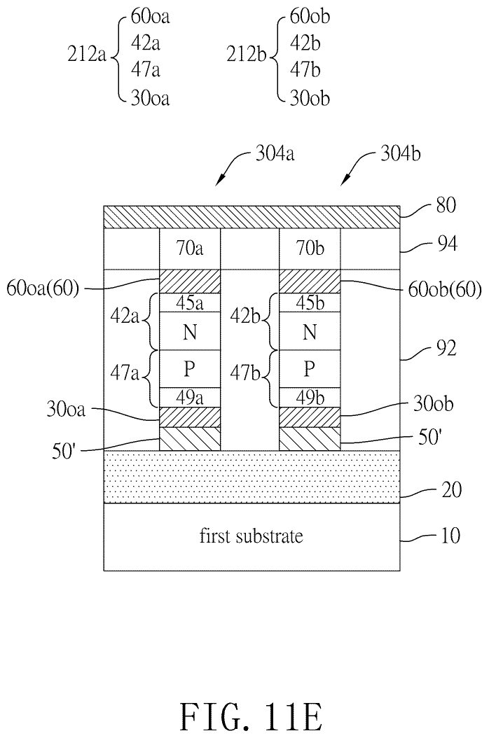

FIGS. 11A to 11E are schematic diagrams illustrating intermediate stages in the manufacture of a semiconductor structure according to one embodiment of the present disclosure.

As shown in FIG. 11A, a second substrate 40 is provided (step (b1)), and a hydrogen layer 41 may be implanted into the second substrate 40 (step (b2)). In the present embodiment, a first opposite-type doped layer 47 is formed in the second substrate 40. The first opposite-type doped layer 47 is of a second conductivity type (e.g., p-type) opposite the first conductivity type. The first opposite-type doped layer 47 may be formed by ion implantation or epitaxial growth. In some embodiments, the first opposite-type doped layer 47 may further comprise a heavily-doped layer 49, wherein the heavily-doped layer 49 is of the second conductivity type. The heavily-doped layer 49 may have a higher doping concentration than that of the first opposite-type doped layer 47. Related details of the second substrate 40 and the implanted hydrogen layer 41 described before may apply here.

As shown in FIG. 11B, a first device metal layer 30 is formed on the second substrate 40 (step (b3)). The first device metal layer 30 may be formed in contact with the heavily-doped layer 49. In the embodiment shown in FIG. 11B, the first device metal layer 30 comprises an Ohmic material layer 300. A first conductive metal layer 50 may be formed on the first device metal layer 30. As such, a second structure 105B is provided (step (b)). The second structure 105B shown in FIG. 11B may be substantially similar to the second structure 100B described above with respect to FIG. 1B, where like reference numerals indicate like elements. In the present embodiment, the second substrate 40 further comprises a first opposite-type doped layer 47 in contact with the first device metal layer 30.

As shown in FIG. 11C, a first structure is provided (step (a)), wherein the first structure comprises a first substrate 10 similar to that described above with respect to FIG. 1C; and, the second structure 105B is flipped and bonded onto the first structure by a bonding layer 20 (step (c)). The bonding process and related details described before may apply here. Then, a portion of the second substrate 40 is removed from approximately the implanted hydrogen layer 41 to form a first semiconductor layer 42 (step (d)). The removal process and the related details described before may apply here.

As shown in FIG. 11D, a second heavily-doped layer 45 is formed (step (h)). In the embodiment shown in FIG. 11D, the second heavily-doped layer 45 is formed after removing a portion of the second substrate 40. Related details of the second heavily-doped layer 45 described before may apply here.

As shown in FIG. 11E, the first semiconductor layer 42 is patterned to form a plurality of semiconductor layers 42a and 42b and semiconductor layers 47a and 47b (step (c)). A second device metal layer 60 is formed (step (f)). In the present embodiment, the second device metal layer 60 comprises a plurality of Ohmic contacts 600a and 60ob. The semiconductor structure shown in FIG. 11E may be formed by processes similar to that described above with respect to FIG. 8C. Related details described above may apply here if applicable. As such, diodes 212a and 212b are provided. The diodes 212a and 212b shown in FIG. 11E may be substantially similar to the diodes 211a and 211b described above with respect to FIG. 8C, where like reference numerals indicate like elements.

Referring to FIG. 11E, the diode 212a comprises the Ohmic contact 300a, the semiconductor layer 42a, the semiconductor layer 47a, and the Ohmic contact 600a. The semiconductor layer 47a is disposed over the Ohmic contact 300a, the semiconductor layer 42a is disposed over the semiconductor layer 47a, and the Ohmic contact 600a is disposed over the semiconductor layer 42a. In other words, the diode 212a may be a “vertical diode”.

The diode 212b comprises the Ohmic contact 30ob, the semiconductor layer 42b, the semiconductor layer 47b, and the Ohmic contact 60ob. The semiconductor layer 47b is disposed over the Ohmic contact 30ob, the semiconductor layer 42b is disposed over the semiconductor layer 47b, and the Ohmic contact 60ob is disposed over the semiconductor layer 42b. In other words, the diode 212b may be a “vertical diode”.

As shown in FIG. 11E, memory units 70a and 70b may be formed (step (i)). In the present embodiment, the memory units 70a and 70b may each comprise a phase-change material or a variable resistance material. A second conductive metal layer 80 may also be formed (step (f)). Details and formation methods of the memory units 70a and 70b and the second conductive metal layer 80 may be similar to that described above with respect to FIG. 1H, and the related description is omitted for brevity. As such, memory cells 304a and 304b are provided. The memory cells 304a and 304b shown in FIG. 11E may be similar to the memory cells 303a and 303b described above with respect to FIG. 8D, where like reference numerals indicate like elements. In the present embodiment, the memory cell 304a comprises the diode 212a and the memory unit 70a, and the memory cell 304b comprises the diode 212b and the memory unit 70b.

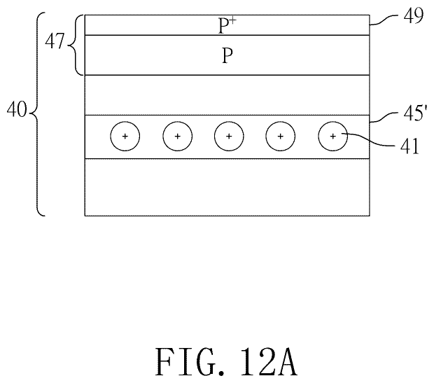

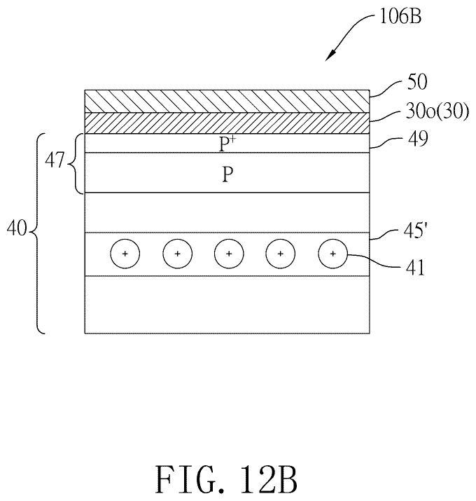

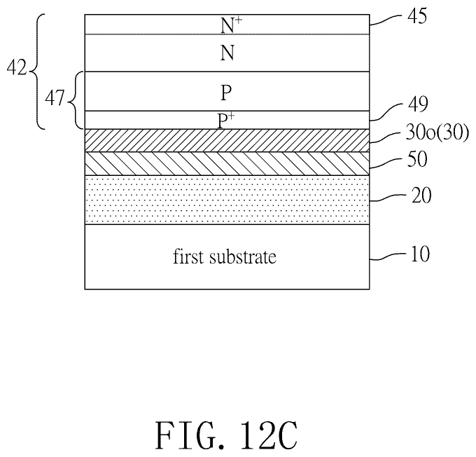

FIGS. 12A to 12C are schematic diagrams illustrating intermediate stages in the manufacture of a semiconductor structure according to one embodiment of the present disclosure.

As shown in FIG. 12A, a second substrate 40 is provided (step (b1)), and a hydrogen layer 41 may be implanted into the second substrate 40 (step (b2)). The semiconductor structure shown in FIG. 12A may be similar to the semiconductor structure shown in FIG. 11A, where like reference numerals indicate like elements. In the present embodiment, a second heavily-doped layer 45′ may be formed at a desired depth from the top surface of the second substrate 40, e.g., by ion implantation. Related details of the second heavily-doped layer 45′ described before may apply here.

As shown in FIG. 12B, a second structure 106B is provided (step (b)). The second structure 106B shown in FIG. 12B may be substantially similar to the second structure 105B described above with respect to FIG. 11B, where like reference numerals indicate like elements. In the present embodiment, the second substrate 40 further comprises a second heavily-doped layer 45′.

As shown in FIG. 12C, a first structure is provided (step (a)), wherein the first structure comprises a first substrate 10 similar to that described above with respect to FIG. 1C; and, the second structure 106B is flipped and bonded onto the first structure by a bonding layer 20 (step (c)). The bonding process and related details described before may apply here.

Then, a portion of the second substrate 40 is removed from approximately the implanted hydrogen layer 41 to form a first semiconductor layer 42 (step (d)). The removal process and the related details described before may apply here. In the present embodiment, the second heavily-doped layer 45 is exposed after removing a portion of the second substrate 40 and planarization of the exposed surface. Semiconductor structures similar to the diodes 212a and 212b and the memory cells 304a and 304b in FIG. 11E may be formed from the structure shown in FIG. 12C by process(es) similar to that described above with respect to FIG. 11E.

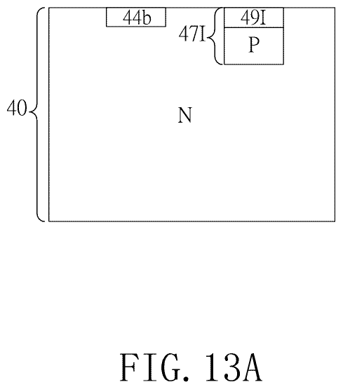

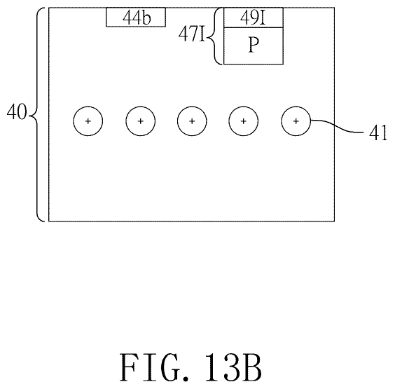

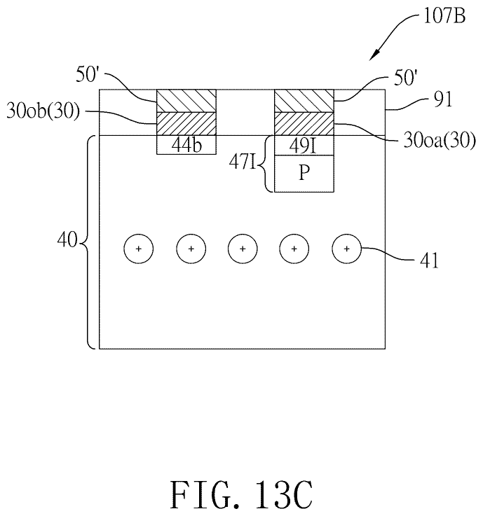

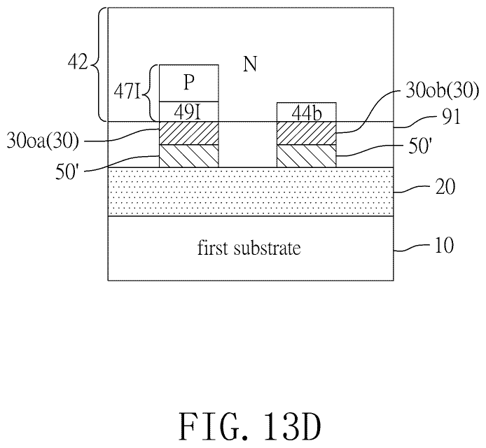

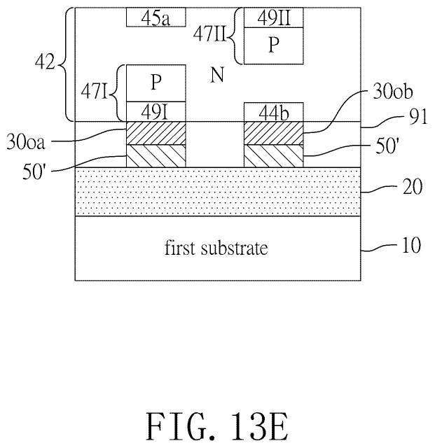

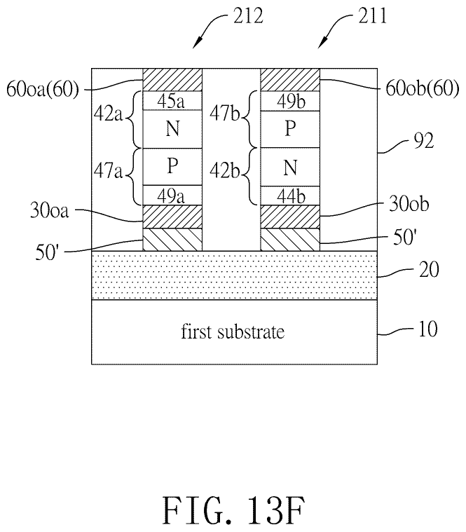

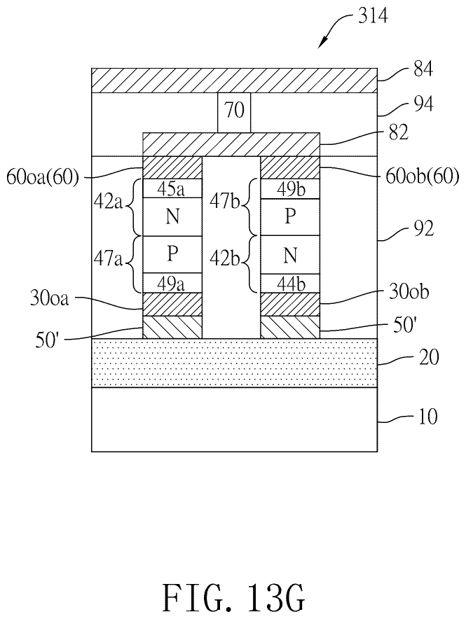

FIGS. 13A to 13G are schematic diagrams illustrating intermediate stages in the manufacture of a semiconductor structure according to one embodiment of the present disclosure.

As shown in FIG. 13A, a second substrate 40 is provided (step (b1)) In the present embodiment, the second substrate 40 comprises a patterned first opposite-type doped layer including a first opposite-type doped region 471 extending from a top surface of the second substrate 40. The patterned first opposite-type doped layer may comprise a patterned heavily-doped layer including a heavily-doped region 491 extending from a top surface of the second substrate 40. Related details of the second substrate 40, the first opposite-type doped layer 47, and the heavily-doped layer 49 described before may apply here if applicable.

In some embodiments, the second substrate 40 may further comprise a patterned first heavily-doped layer including a heavily-doped region 44b extending from a top surface of the second substrate 40. Related details of the heavily-doped region 44a described above with respect to FIG. 6A may apply here.

As shown in FIG. 13B, a hydrogen layer 41 may be implanted into the second substrate 40 (step (b2)). Related details of the implanted hydrogen layer 41 described before may apply here.

As shown in FIG. 13C, a first device metal layer 30 is formed on the second substrate 40 (step (b3)). In the embodiment shown in FIG. 13C, the first device metal layer 30 comprises an Ohmic contacts 300a and 30ob. The Ohmic contact 300a may be formed in contact with the first opposite-type doped region 471 and the heavily-doped region 491, and the Ohmic contact 30ob may be formed in contact with the heavily-doped region 44b. A first conductive metal layer 50′ may be formed on the Ohmic contacts 300a and 30ob. As such, a second structure 107B is provided (step (b)). Related details of the first device metal layer 30 and the first conductive metal layer 50′ described before may apply here.

As shown in FIG. 13D, a first structure is provided (step (a)), wherein the first structure comprises a first substrate 10 similar to that described above with respect to FIG. 1C; and, the second structure 107B is flipped and bonded onto the first structure by a bonding layer 20 (step (c)). The bonding process and related details described before may apply here. Then, a portion of the second substrate 40 is removed from approximately the implanted hydrogen layer 41 to form a first semiconductor layer 42 (step (d)). The removal process and the related details described before may apply here.

As shown in FIG. 13E, a second opposite-type doped layer is formed (step (j2)). The second opposite-type doped layer is of the second conductivity type opposite the first conductivity type. The second opposite-type doped layer may be a patterned layer and may include a second opposite-type doped region 47II extending from an exposed surface of the first semiconductor layer 42. The second opposite-type doped layer may be formed after removing a portion of the second substrate 40. The second opposite-type doped layer may be similar to the first opposite-type doped layer and may be formed by similar methods described above. The patterned second opposite-type doped layer may comprise a patterned heavily-doped layer including a heavily-doped region 49II extending from the exposed surface of the first semiconductor layer 42.

In some embodiments, a patterned second heavily-doped layer including a heavily-doped region 45a extending from the exposed surface of the first semiconductor layer 42 may be formed. Related details of the heavily-doped region 45b described above with respect to FIG. 6E may apply here.

As shown in FIG. 13F, the first semiconductor layer 42 is patterned to form a plurality of semiconductor layers 42a and 42b and semiconductor layers 47a and 47b (step (e)). A second device metal layer 60 is formed (step (f)). In the present embodiment, the second device metal layer 60 comprises a plurality of Ohmic contacts 600a and 60ob. The semiconductor structure shown in FIG. 13F may be formed by processes similar to that described above with respect to FIG. 8C. Related details described above may apply here if applicable.

Referring to FIG. 13F, diodes 211 and 212 are provided. The diode 211 shown in FIG. 13F may be substantially similar to the diodes 211a and 211b described above with respect to FIG. 8C, where like reference numerals indicate like elements. The diode 212 shown in FIG. 13F may be substantially similar to the diodes 212a and 212b described above with respect to FIG. 11E, where like reference numerals indicate like elements. Related details described above may apply here if applicable.

In the present embodiment, the vertical diodes 211 and 212, which are manufactured under the same set of processes, are formed to be arranged in opposite directions. Such configuration may render a simplified routing and a reduced thickness of the overall semiconductor device.

As shown in FIG. 13G, a memory unit 70 may be formed (step (i)). The memory unit 70 may be similar to that discussed above with respect to FIG. 3. In the embodiment shown in FIG. 13G, a third wiring layer 82 may be formed, such that the Ohmic contact 600a of the diode 212 is electrically coupled to the Ohmic contact 60ob of the diode 211 through conductive feature(s) of the third wiring layer 82. A second wiring layer 84 may also be formed after the formation of the memory unit 70.

Referring to FIG. 13G, a memory cell 314 is provided. The memory cell 314 shown in FIG. 13G may be substantially similar to the memory cell 312 described above with respect to FIG. 6G, where like reference numerals indicate like elements. In the present embodiment, the memory cell 314 comprises diodes 211 and 212 and a memory unit 70. The memory unit 70 is electrically coupled to both the Ohmic contact 600a of the diode 212 and the Ohmic contact 60ob of the diode 211 from a first end of the memory unit 70 and electrically coupled to the second wiring layer 84 from a second end of the memory unit 70. The memory cell 314 shown in FIG. 13G may be a spin-transfer torque type MRAM (STT-MRAM) cell, and the first wiring layer 50′ and the second wiring layer 84 may serve as bit lines and/or word lines for the memory cell. Despite that only two diodes and one memory cell is illustrated in FIG. 13G, a plurality of diodes and memory cells or an array of diodes and memory cells can be fabricated at the same time using the method disclosed herein.

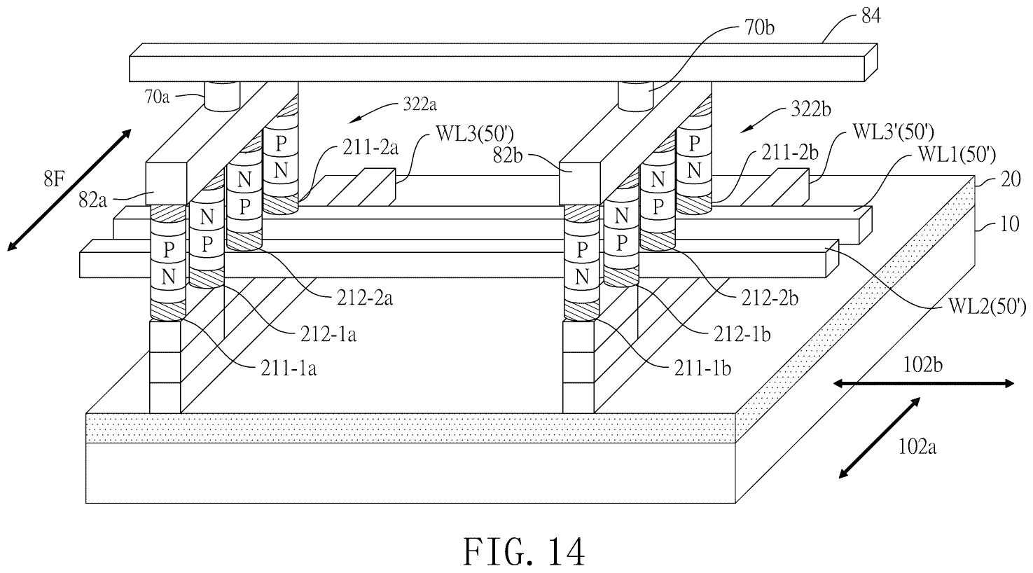

FIG. 14 is a schematic view to illustrate an embodiment of a memory device according to the present disclosure. As shown in FIG. 14, memory cells 322a and 322b are provided. The memory cells 322a and 322b or similar semiconductor structures may be formed by processes similar to that described herein with respect to FIGS. 13A to 13G. The memory cells 322a and 322b shown in FIG. 14 may be substantially similar to the memory cells 321a and 321b described above with respect to FIG. 7, where like reference numerals indicate like elements. Related details of the memory cells 321a and 321b described above may apply here if applicable.

Specifically, in the present embodiment, the memory cell 322a comprises a first pair of diodes 211-1a and 212-1a, a second pair of diodes 211-2a and 212-2a, an electrode 82a, and a memory unit 70a; the memory cell 322b comprises a first pair of diodes 211-1b and 212-1b, a second pair of diodes 211-2b and 212-2b, an electrode 82b, and a memory unit 70b. The diodes 211-1a, 211-2a, 211-1b, and 211-2b may be substantially similar to the diodes 211a and 211b described above with respect to FIG. 8C; the diodes 212-1a, 212-2a, 212-1b, and 212-2b may be substantially similar to the diodes 212a and 212b described above with respect to FIG. 11E, where like reference numerals indicate like elements.

Referring to FIG. 14, both the diodes 211-1a and 212-1a are electrically coupled to the electrode 82a at a first side of the memory unit 70a, and both the diodes 211-2a and 212-2a are electrically coupled to the electrode 82a at a second side of the memory unit 70a. Similarly, both the diodes 211-1b and 212-1b are electrically coupled to the electrode 82b at a first side of the memory unit 70b, and both the diodes 211-2b and 212-2b are electrically coupled to the electrode 82b at a second side of the memory unit 70b.

Each of the memory cells 322a and 322b shown in FIG. 14 may be a SOT-MRAM cell, and the first wiring layer 50′ and the second wiring layer 84 may serve as bit lines and/or word lines for the memory cells. As shown in FIG. 14, each of the memory cells 322a and 322b may have a cell dimension of 8F and 2F respectively in the first direction 102a and the second direction 102b, which provides a cell size of 16 feature squares (F²). Despite that only two memory cells are illustrated in FIG. 14, a plurality of memory cells or an array of cells can be fabricated at the same time using the method disclosed herein.

The foregoing description of embodiments is provided to enable any person skilled in the art to make and use the subject matter. Various modifications to these embodiments will be readily apparent to those skilled in the art, and the novel principles and subject matter disclosed herein may be applied to other embodiments without the use of the innovative faculty. The claimed subject matter set forth in the claims is not intended to be limited to the embodiments shown herein but is to be accorded the widest scope consistent with the principles and novel features disclosed herein. It is contemplated that additional embodiments are within the spirit and true scope of the disclosed subject matter. Thus, it is intended that the present invention covers modifications and variations that come within the scope of the appended claims and their equivalents.

What is claimed is:

1. A method for manufacturing a semiconductor structure, comprising:
(a) providing a first structure comprising a first substrate;
(b) providing a second structure comprising a second substrate and a first device metal layer on and in contact with the second substrate, wherein the second substrate comprises a single crystalline semiconductor material and an implanted hydrogen layer;
(c) bonding the first structure and the second structure by a bonding layer to form a bonded structure;
(d) removing a portion of the second substrate from approximately the implanted hydrogen layer to form a first semiconductor layer;
(e) patterning the first semiconductor layer; and
(f) forming at least one of a second device metal layer and a second conductive metal layer.

2. The method of claim 1, wherein the second structure further comprises a first conductive metal layer, and wherein the first device metal layer is disposed between the first conductive metal layer and the second substrate.

3. The method of claim 1, wherein the step (b) comprises:
(b1) providing the second substrate;
(b2) implanting the hydrogen layer into the second substrate; and
(b3) forming the first device metal layer on the second substrate.

4. The method of claim 1, wherein the step (c) comprises forming a first dielectric layer on the first substrate and forming a second dielectric layer on the first device metal layer before bonding.

5. The method of claim 1, wherein the first substrate comprises single crystalline semiconductor material, polycrystalline semiconductor material, glass, or ceramic.

6. The method of claim 1, wherein the first device metal layer comprises a Schottky material layer.

7. The method of claim 1, wherein the first device metal layer comprises a plurality of Schottky contacts.

8. The method of claim 1, wherein the first device metal layer comprises an Ohmic material layer.

9. The method of claim 1, wherein the first device metal layer comprises a plurality of Ohmic contacts.

10. The method of claim 1, wherein the first device metal layer comprises a patterned Schottky material layer and either one of a patterned Ohmic material layer and an Ohmic contact.

11. The method of claim 1, wherein the first device metal layer comprises a patterned Ohmic material layer and either one of a patterned Schottky material layer and a Schottky contact.

12. The method of claim 1, wherein the step (f) comprises forming the second device metal layer, and the second device metal layer comprises a plurality of Schottky contacts.

13. The method of claim 1, wherein the step (f) comprises forming the second device metal layer, and the second device metal layer comprises a plurality of Ohmic contacts.

14. The method of claim 1, wherein the step (f) comprises forming the second device metal layer, and the second device metal layer comprises both a plurality of Schottky contacts and a plurality of Ohmic contacts.

15. The method of claim 1, wherein the first semiconductor layer is of a first conductivity type.

16. The method of claim 1, wherein in the step (b) the second substrate further comprises a first heavily-doped layer in contact with the first device metal layer.

17. The method of claim 16, wherein the first heavily-doped layer is patterned.

18. The method of claim 16, wherein the first heavily-doped layer is of a first conductivity type.

19. The method of claim 1 further comprising (h) forming a second heavily-doped layer either in the first semiconductor layer or on the first semiconductor layer after the step (d).

20. The method of claim 19, wherein the second heavily-doped layer is patterned.

21. The method of claim 19, wherein the second heavily-doped layer is of a first conductivity type.

22. The method of claim 1, wherein in the step (b) the second substrate further comprises a second heavily-doped layer, and the second heavily-doped layer is exposed after the step (d).

23. The method of claim 1 further comprising (i) forming a memory unit after the step (d).

24. The method of claim 1 further comprising (j1) forming a second semiconductor layer on an exposed surface of the first semiconductor layer after the step (d).

25. The method of claim 24, wherein the second semiconductor layer is of a second conductivity type opposite a first conductivity type.

26. The method of claim 24, wherein the step (e) further comprising patterning the second semiconductor layer.

27. The method of claim 1 further comprising (j2) forming a second opposite-type doped layer extending from an exposed surface of the first semiconductor layer after the step (d).

28. The method of claim 27, wherein the second opposite-type doped layer is of a second conductivity type opposite a first conductivity type.

29. The method of claim 27, wherein the second opposite-type doped layer is patterned.

30. The method of claim 1, wherein in the step (b) the second substrate further comprises a first opposite-type doped layer in contact with the first device metal layer.

31. The method of claim 30, wherein the first opposite-type doped layer is of a second conductivity type opposite a first conductivity type.

32. The method of claim 30, wherein the first opposite-type doped layer is patterned.
